(19) United States
(12) Patent Application Publication
(10) Pub. No.: US 2026/0231473 A1
(43) Pub. Date: Aug. 6, 2026

(54) THIN FILM TRANSISTOR AND MANUFACTURING METHOD THEREFOR, AND LIGHT-EMITTING SUBSTRATE

(71) Applicants: Beijing BOE Technology Development Co., Ltd., Beijing (CN); BOE Technology Group Co., Ltd., Beijing (CN)

(72) Inventor: Feng GUAN, Beijing (CN)

(73) Assignees: Beijing BOE Technology Development Co., Ltd., Beijing (CN); BOE Technology Group Co., Ltd., Beijing (CN)

(21) Appl. No.: 19/152,458

(22) PCT Filed: Jun. 14, 2024
(86) PCT No.: PCT/CN2024/099114

§ 371 Date: Jul. 31, 2025

(30) Foreign Application Priority Data
Jul. 21, 2023 (CN) 202310906761.2

(51) Int. Cl. H10D 30/67; H10D 30/01

(52) U.S. Cl. CPC H10D 30/6734; H10D 30/0312; H10D 30/6719; H10D 30/6757

(57) ABSTRACT

A thin film transistor includes a substrate, a first gate, an active layer, and a second gate that are arranged sequentially, and a first electrode and second electrode. An orthographic projection of the first gate on the substrate at least partially overlaps with an orthographic projection of a second heavily doped region included in the active layer on the substrate. A first via connection portion of the first electrode is electrically connected to a first main portion of the first electrode and a first heavily doped region included in the active layer; a second via connection portion of the second electrode is electrically connected a second main portion of the second electrode and the second heavily doped region and first gate; an orthographic projection of the second via connection portion on the substrate is located within the orthographic projection of the second heavily doped region on the substrate.

### CROSS-REFERENCE TO RELATED APPLICATIONS

This application is a national phase entry under 35 USC 371 of International Patent Application No. PCT/CN 2024/099114, filed on Jun. 14, 2024, which claims priority to Chinese Patent Application No. 202310906761.2, filed on Jul. 21, 2023, each are incorporated herein by reference in their entirety.

### TECHNICAL FIELD

The present disclosure relates to the field of display technologies, and in particular, to a thin film transistor and a manufacturing method therefor, and a light-emitting substrate.

### BACKGROUND

Due to the defect problems of amorphous silicon (a-Si) itself, such as low on-state current, low mobility and poor stability caused by many defect states, the application of amorphous silicon is limited in many fields. In order to make up for the defects of amorphous silicon itself and expand the application of related products in related fields, low-temperature polycrystalline silicon (LTPS, p-Si for short) technologies came into being.

### SUMMARY

In an aspect, a thin film transistor is provided. The thin film transistor includes a substrate, an active layer, a first gate, a second gate, a first electrode and a second electrode. The active layer is located on a side of the substrate, and the active layer includes a channel and a first heavily doped region and a second heavily doped region that are located on two sides of the channel. The first gate is located on a side of the active layer proximate to the substrate. The second gate is located on a side of the active layer away from the first gate, an orthographic projection of the first gate on the substrate at least partially overlaps with an orthographic projection of the second heavily doped region on the substrate. The first electrode includes a first main portion and a first via connection portion, and the second electrode includes a second main portion and a second via connection portion. The first main portion and the second main portion are located on a side of the second gate away from the active layer. The first via connection portion is electrically connected to the first main portion and the first heavily doped region, the second via connection portion is electrically connected the second main portion and the second heavily doped region and first gate, and an orthographic projection of the second via connection portion on the substrate is located within the orthographic projection of the second heavily doped region on the substrate.

In some embodiments, the second heavily doped region includes at least one via hole, an end of the second via connection portion is electrically connected to the second main portion, and another end of the second via connection portion penetrates the via hole to be electrically connected to the first gate.

In some embodiments, the orthographic projection of the first gate on the substrate is non-overlapping with an orthographic projection of the first via connection portion on the substrate.

In some embodiments, a minimum spacing between the orthographic projection of the first gate on the substrate and an orthographic projection of the first via connection portion on the substrate is greater than or equal to 0.5 μm.

In some embodiments, an orthographic projection of the channel on the substrate is located within the orthographic projection of the first gate on the substrate, and a minimum spacing between an outer edge of the orthographic projection of the first gate on the substrate and an outer edge of the orthographic projection of the channel on the substrate is greater than or equal to 0.5 μm.

In some embodiments, the orthographic projection of the second heavily doped region on the substrate is located within the orthographic projection of the first gate on the substrate.

In some embodiments, in a first direction, the first gate includes a first side and a second side that are oppositely arranged, and the first side is located on a side of the second side away from the first via connection portion; the first direction is a direction from the first electrode to the second electrode. A minimum spacing between an orthographic projection of the first side of the first gate on the substrate and an orthographic projection of a third side, away from the first heavily doped region, of the second heavily doped region on the substrate is greater than or equal to 0.5 μm.

In some embodiments, the minimum spacing between the orthographic projection of the first side of the first gate on the substrate and the orthographic projection of the third side, away from the first heavily doped region, of the second heavily doped region on the substrate is less than or equal to 10 μm.

In some embodiments, an end of the second via connection portion is electrically connected to the second main portion of the second electrode, and another end of the second via connection portion is electrically connected to the first gate through the second heavily doped region.

In some embodiments, an orthographic projection of the channel on the substrate is located within the orthographic projection of the first gate on the substrate; a minimum spacing between an outer edge of the orthographic projection of the first gate on the substrate and an outer edge of the orthographic projection of the channel on the substrate is greater than or equal to 0.5 μm.

In some embodiments, an orthographic projection of the active layer on the substrate is located within the orthographic projection of the first gate on the substrate.

In some embodiments, a minimum spacing between an outer edge of the orthographic projection of the first gate on the substrate and an outer edge of an orthographic projection of the active layer on the substrate is greater than or equal to 0.5 μm.

In some embodiments, the minimum spacing between the outer edge of the orthographic projection of the first gate on the substrate and the outer edge of the orthographic projection of the active layer on the substrate is less than or equal to 10 μm.

In some embodiments, the active layer further includes a first lightly doped drain and a second lightly doped drain. The first lightly doped drain is located between the first heavily doped region and the channel, and a doping concentration of the first lightly doped drain is less than a doping concentration of the first heavily doped region. The second lightly doped drain is located between the second heavily doped region and the channel, and a doping concentration of the second lightly doped drain is less than a doping concentration of the second heavily doped region.

In some embodiments, in a sectional view of the thin film transistor taken along a first direction, an orthographic projection of the second gate on the substrate substantially coincides with an orthographic projection of the channel on the substrate; the first direction is a direction from the first electrode to the second electrode.

In some embodiments, a thickness of the active layer is in a range of 100 Å to 1000 Å, inclusive.

In another aspect, a manufacturing method for a thin film transistor is provided. The manufacturing method for the thin film transistor includes: forming a first gate on a side of a substrate; forming an active layer on a side of the substrate away from the first gate, the active layer including a channel and a first to-be-doped region and a second to-be-doped region that are located on two sides of the channel, and an orthographic projection of the first gate on the substrate at least partially overlapping with an orthographic projection of the second to-be-doped region on the substrate; forming a second gate on a side of the active layer away from the substrate; performing a conductorization process on the first to-be-doped region and the second to-be-doped region to respectively form a first heavily doped region and a second heavily doped region; and forming a first electrode and a second electrode on a side of the first gate away from the substrate. The first electrode includes a first via connection portion, the first via connection portion is electrically connected to the first heavily doped region; the second electrode includes a second via connection portion, the second via connection portion is electrically connected to the second heavily doped region and the first gate, and an orthographic projection of the second via connection portion on the substrate is located within an orthographic projection of the second heavily doped region on the substrate.

In some embodiments, before forming the first electrode and the second electrode on the side of the first gate away from the substrate, the manufacturing method further includes: forming a via hole in the second heavily doped region. Forming the second electrode includes: the second via connection portion of the second electrode penetrating the via hole to be electrically connected to the first gate.

In yet another aspect, a manufacturing method for a thin film transistor is provided. The manufacturing method for the thin film transistor includes: forming a first gate on a side of a substrate; forming an active layer on a side of the substrate away from the first gate, the active layer including a channel and a first to-be-doped region and a second to-be-doped region that are located on two sides of the channel, an orthographic projection of the first gate on the substrate at least partially overlapping with an orthographic projection of the second to-be-doped region on the substrate, the second to-be-doped region including a third via connection portion, and the third via connection portion being electrically connected to the first gate; forming a second gate on a side of the active layer away from the substrate; performing a conductorization process on the first to-be-doped region and the second to-be-doped region to respectively form a first heavily doped region and a second heavily doped region; and forming a first electrode and a second electrode on a side of the first gate away from the substrate. The first electrode includes a first via connection portion, and the first via connection portion is electrically connected to the first heavily doped region; the second electrode includes a second via connection portion, and the second via connection portion is electrically connected to the second heavily doped region; an orthographic projection of the second via connection portion on the substrate is within an orthographic projection of the second heavily doped region on the substrate.

In still yet another aspect, a light-emitting substrate is provided. The light-emitting substrate includes the thin film transistor as described in any of the above embodiments.

### BRIEF DESCRIPTION OF THE DRAWINGS

In order to describe technical solutions in the present disclosure more clearly, the accompanying drawings to be used in some embodiments of the present disclosure will be introduced briefly. Obviously, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a structural diagram of a display apparatus, in accordance with some embodiments;

FIG. 2 is a structural diagram of a light-emitting substrate, in accordance with some embodiments;

FIG. 3 is a circuit diagram of a light-emitting driving circuit, in accordance with some embodiments;

FIG. 4 is a structural diagram of a thin film transistor, in accordance with some implementions;

FIG. 5 is a structural diagram of a thin film transistor, in accordance with some embodiments;

FIG. 6 is a diagram showing film layers of a thin film transistor, in accordance with some embodiments;

FIG. 7 is a structural diagram of another thin film transistor, in accordance with some embodiments;

FIG. 8 is a diagram showing film layers of another thin film transistor, in accordance with some embodiments;

FIG. 9 is a diagram showing film layers of yet another thin film transistor, in accordance with some embodiments;

FIG. 10 is a diagram showing film layers of yet another thin film transistor, in accordance with some embodiments;

FIG. 11 is a flowchart of a manufacturing method for a thin film transistor, in accordance with some embodiments;

FIG. 12 is a structural diagram showing film layers corresponding to steps in FIG. 11;

FIG. 13 is a top view corresponding to some steps in FIG. 11;

FIG. 14 is a top view corresponding to some other steps in FIG. 11;

FIG. 15 is a structural diagram showing film layers corresponding to step S14 in FIG. 11;

FIG. 16 is a top view corresponding to step S14 in FIG. 11;

FIG. 17 is a flowchart of a manufacturing method for another thin film transistor, in accordance with some embodiments;

FIG. 18 is a structural diagram showing film layers corresponding to steps in FIG. 17; and FIG. 19 is a structural diagram of a manufacturing method for a thin film transistor, in accordance with some embodiments.

### DETAILED DESCRIPTION

The technical solutions in some embodiments of the present disclosure will be described clearly and completely below with reference to the accompanying drawings, and obviously, the described embodiments are merely some but not all embodiments of the present disclosure. All other embodiments obtained by a person of ordinary skill in the art based on the embodiments of the present disclosure shall be included in the protection scope of the present disclosure.

Unless the context requires otherwise, throughout the specification and the claims, the term “comprise” and other forms thereof such as the third-person singular form “comprises” and the present participle form “comprising” are construed as an open and inclusive meaning, i.e., “including, but not limited to”. In the description of the specification, the terms such as “one embodiment”, “some embodiments”, “exemplary embodiments”, “example”, “specific example”, or “some examples” are intended to indicate that specific features, structures, materials, or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics may be included in any one or more embodiments or examples in any suitable manner.

Hereinafter, the terms “first” and “second” are only used for descriptive purposes, and are not to be construed as indicating or implying the relative importance or implicitly indicating the number of indicated technical features. Thus, a feature defined by “first” or “second” may explicitly or implicitly include one or more of the features. In the description of the embodiments of the present disclosure, the term “a plurality of” or “the plurality of” means two or more unless otherwise specified.

In the description of some embodiments, the expressions “coupled”, “connected”, and derivatives thereof may be used. The term “connected” should be understood in a broad sense. For example, the term “connected” may represent a fixed connection, a detachable connection, or a one-piece connection, or may represent a direct connection, or may represent an indirect connection through an intermediate medium. The term “coupled” indicates, for example, that two or more components are in direct physical or electrical contact. The term “coupled” or “communicatively coupled” may also indicate that two or more components are not in direct contact with each other, but still cooperate or interact with each other. The embodiments disclosed herein are not necessarily limited to the content herein.

The phrase “at least one of A, B, and C” has the same meaning as the phrase “at least one of A, B, or C,” both including the following combinations of A, B, and C, only A, only B, only C, a combination of A and B, a combination of A and C, a combination of B and C, and a combination of A, B, and C.

The phrase “A and/or B” includes the following three combinations: only A, only B, and a combination of A and B.

As used herein, the term “if” is, optionally, construed as “when” or “in a case where” or “in response to determining that” or “in response to detecting”, depending on the context. Similarly, depending on the context, the phrase “if it is determined that” or “if [a stated condition or event] is detected” is optionally construed as “in a case where it is determined that” or “in response to determining that” or “in a case where [the stated condition or event] is detected” or “in response to detecting [the stated condition or event]”.

The use of “applicable to” or “configured to” herein means an open and inclusive expression, which does not exclude devices that are applicable to or configured to perform additional tasks or steps.

Additionally, the use of the phrase “based on” is meant to be open and inclusive, since a process, step, calculation or other action that is “based on” one or more of the stated conditions or values may, in practice, be based on additional conditions or value beyond those stated.

The term such as “about”, “substantially”, or “approximately” as used herein includes a stated value and an average value within an acceptable range of deviation of a particular value determined by a person of ordinary skill in the art, considering measurement in question and errors associated with measurement of a particular quantity (i.e., limitations of a measurement system).

The term “perpendicular” as used herein includes a stated condition and a condition similar to the stated condition. A range of the similar condition is within an acceptable deviation range, and the acceptable deviation range is determined by a person of ordinary skill in the art, considering measurement in question and errors associated with measurement of a particular quantity (i.e., the limitations of a measurement system). For example, the term “perpendicular” includes absolute perpendicularity and approximate perpendicularity, and an acceptable range of deviation of the approximate perpendicularity may be, for example, a deviation within 5°.

It will be understood that, in a case where a layer or component is referred to as being on another layer or a substrate, it may be that the layer or component is directly on the another layer or substrate, or there may be intervening layer(s) between the layer or component and the another layer or substrate.

Exemplary embodiments are described herein with reference to sectional views and/or plan views as idealized exemplary drawings. In the accompanying drawings, thickness of layers and sizes of regions are enlarged for clarity. Variations in shape relative to the accompanying drawings due to, for example, manufacturing technologies and/or tolerances may be envisaged. Therefore, the exemplary embodiments should not be construed as being limited to the shapes of the regions shown herein, but including deviations due to, for example, manufacturing. For example, an etched region shown in a rectangular shape generally has a feature of being curved. Therefore, the regions shown in the accompanying drawings are schematic in nature, and their shapes are not intended to show actual shapes of the regions in an apparatus, and are not intended to limit the scope of the exemplary embodiments.

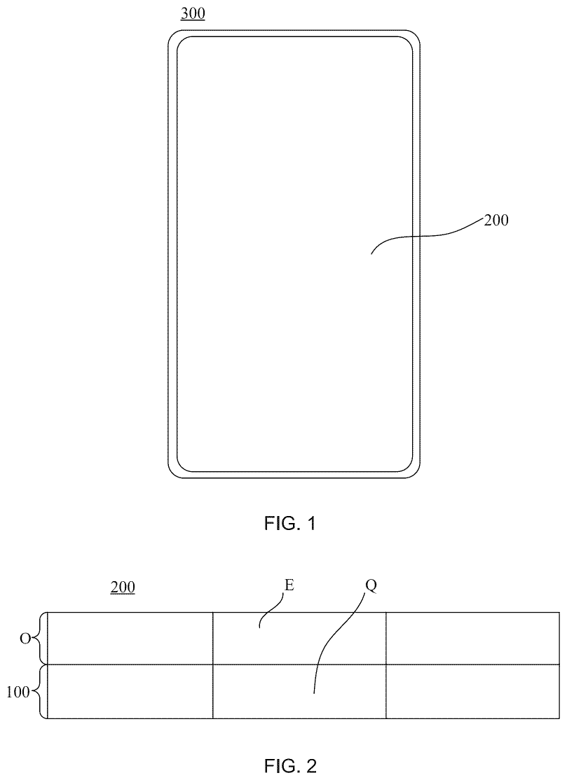

FIG. 1 is a structural diagram of a display apparatus, in accordance with some embodiments.

Some embodiments of the present disclosure provide a display apparatus. Referring to FIG. 1, the display apparatus 300 includes a light-emitting substrate 200.

In some examples, the display apparatus 300 may be any device that displays an image whether in motion (e.g., a video) or stationary (e.g., a still image), and whether textual or graphical. More specifically, it is expected that the embodiments may be implemented in or associated with various electronic devices, which include (but is not limit to), for example, a mobile phone, a wireless device, a personal digital assistant (PDA), a hand-held or portable computer, a GPS receiver/navigator, a camera, an MP4 video player, a video camera, a game console, a watch, a clock, a calculator, a TV monitor, a flat panel display, a computer monitor, a car display (e.g., an odometer display), a navigator, a cockpit controller and/or display, a display in camera view (e.g., a display for a rear camera in a vehicle), an electronic photo, an electronic billboard or indicator, a projector, a building structure, a packaging and aesthetic structure (e.g., a display for an image of a piece of jewelry).

For example, the display apparatus 300 may be a liquid crystal display (LCD) apparatus, a mini light-emitting diode (mini LED) display apparatus, and a micro light-emitting diode (micro LED) display apparatus.

In some embodiments, in a case where the display apparatus 300 is a liquid crystal display apparatus, the display apparatus 300 includes a cover glass, a liquid crystal display panel, and a backlight assembly. The backlight assembly is used to provide backlight for the liquid crystal display panel. The backlight assembly includes a light-emitting substrate 200, and the light-emitting substrate 200 provides a light source for the liquid crystal display panel, so that the liquid crystal display panel may display images.

In some examples, the display apparatus 300 may include an array substrate, an opposite substrate (which may be a color filter substrate), and a liquid crystal layer. The opposite substrate and the array substrate are oppositely arranged, and the liquid crystal layer is located between the opposite substrate and the array substrate.

A first polarizer is provided on the array substrate, and a second polarizer is provided on the opposite substrate, and polarization directions of the first polarizer and the second polarizer are perpendicular to each other. The liquid crystal molecules of the liquid crystal layer deflect due to the action of a driving electric field created between a pixel electrode provided in the array substrate and a common electrode provided in the array substrate or provided in the opposite substrate, so as to control the polarization direction of light and controlling the transmittance of light in cooperation with the first polarizer and the second polarizer, thereby achieving grayscale display.

In some embodiments, in a case where the display apparatus 300 is a mini LED display apparatus, or a micro LED display apparatus, the display apparatus 300 includes a light-emitting substrate 200, and the light-emitting substrate 200 may achieve the image display. In some examples, the display apparatus 300 may further include an anti-reflection film layer and a protective cover plate, and the anti-reflection film layer is located between the light-emitting substrate 200 and the protective cover plate. The anti-reflection film layer includes a polarizer, and the polarizer may be a circular polarizer. Here, the polarizer may reduce reflection of external light to prevent the dazzling effect caused by a fact that the light-emitting substrate 200 reflects the ambient light.

FIG. 2 is a structural diagram of a light-emitting substrate, in accordance with some embodiments.

In some embodiments, referring to FIG. 2, the light-emitting substrate 200 may include a driving circuit layer 100 and a light source O. The light source O may include a plurality of light-emitting devices E, and the driving circuit layer 100 may include a plurality of light-emitting driving circuits Q. The plurality of light-emitting driving circuits Q in the driving circuit layer 100 are electrically connected to the plurality of light-emitting devices E in the light source O, so that the light-emitting driving circuits Q are used to drive the light-emitting devices E to emit light.

In some examples, the plurality of light-emitting driving circuit Q may be electrically connected to the plurality of light-emitting devices E in one-to-one correspondence. In some other examples, a light-emitting driving circuit Q may be coupled to multiple light-emitting devices E, or multiple light-emitting driving circuit Q may be coupled to a light-emitting device E. The following description will be made by taking an example in which the plurality of light-emitting driving circuits Q and the plurality of light-emitting devices E are electrically connected in a one-to-one correspondence.

In some examples, the light-emitting device E may be at least one of a light-emitting diode (LED), a micro light-emitting diode (micro LED), and a mini light-emitting diode (a mini LED), and the present disclosure is not limited thereto. The following description will be introduced by taking an example in which the light-emitting device E is a micro LED.

In some embodiments, a structure of the light-emitting driving circuit Q varies, which may be set according to actual needs. For example, the structure of the light-emitting driving circuits Q may include an “8T2C” structure or an “11T3C” structure. Here, “T” represents a thin film transistor, a number before “T” represents the number of thin film transistors, “C” represents a storage capacitor C, and a number before “C” represents the number of storage capacitors C.

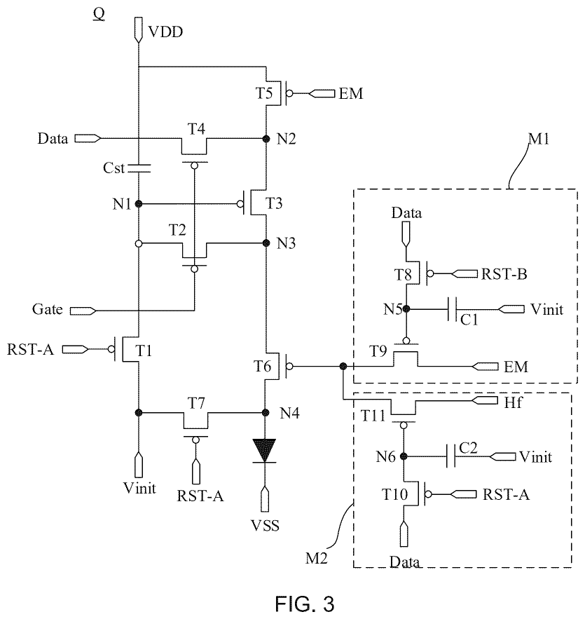

FIG. 3 is a circuit diagram of a light-emitting driving circuit, in accordance with some embodiments.

In some embodiments, referring to FIGS. 2 and 3, and the description is made by taking an example in which the structure of the light-emitting driving circuit Q is “11T3C”. Here, “11T” may represent 11 thin film transistors T.

The light-emitting driving circuit Q includes a storage capacitor Cst, a first reset transistor T1, a compensation transistor T2, a driving transistor T3, a data writing transistor T4, a first light-emitting control transistor T5, a second light-emitting control transistor T6, a second reset transistor T7, a first regulating unit M1, and a second regulating unit M2. When operating at different gray scales, the first regulating unit M1 or the second regulating unit M2 is used to control the second light-emitting control transistor T6. The first regulating unit M1 includes a first writing transistor T8, a first regulating transistor T9 and a first capacitor C1. The second regulating unit M2 includes a second writing transistor T10, a second regulating transistor T11, and a second capacitor C2.

The first reset transistor T1, the compensation transistor T2, the driving transistor T3, the data writing transistor T4, the first light-emitting control transistor T5, the second light-emitting control transistor T6, the second reset transistor T7, the first writing transistor T8, the first regulating transistor T9, the second writing transistor T10, and the second regulating transistor T11 are all thin film transistors.

In some examples, the above “11T” may be P-type transistor. That is, the first reset transistor T1, the compensation transistor T2, the driving transistor T3, the data writing transistor T4, the first light-emitting control transistor T5, the second light-emitting control transistor T6, the second reset transistor T7, the first writing transistor T8, the first regulating transistor T9, the second writing transistor T10, and the second regulating transistor T11 are all P-type transistors.

In some other examples, the above “11T” may be N-type transistor. That is, the first reset transistor T1, the compensation transistor T2, the driving transistor T3, the data writing transistor T4, the first light-emitting control transistor T5, the second light-emitting control transistor T6, the second reset transistor T7, the first writing transistor T8, the first regulating transistor T9, the second writing transistor T10, and the second regulating transistor T11 are all N-type transistors.

A first plate of the storage capacitor Cst is electrically connected to the first voltage signal line VDD, and a second plate of the storage capacitor Cst is electrically connected to a first node N1.

A control electrode of the first reset transistor T1 is electrically connected to a first reset signal line RST-A, a first electrode of the first reset transistor T1 is electrically connected to a first initialization signal line Vinit, and a second electrode of the first reset transistor T1 is electrically connected to the first node N1.

A control electrode of the compensation transistor T2 is electrically connected to a first scanning signal line Gate, a first electrode of the compensation transistor T2 is electrically connected to the first node N1, and a second electrode of the compensation transistor T2 is electrically connected to a third node N3.

A control electrode of the driving transistor T3 is electrically connected to the first node N1, a first electrode of the driving transistor T3 is electrically connected to a second node N2, and a second electrode of the driving transistor T3 is electrically connected to the third node N3.

A control electrode of the data writing transistor T4 is electrically connected to the first scanning signal line Gate, a first electrode of the data writing transistor T4 is electrically connected to the data writing signal line Data, and a second electrode of the data writing transistor T4 is electrically connected to the second node N2.

A control electrode of the first light-emitting control transistor T5 is electrically connected to an enable signal line EM, a first electrode of the first light-emitting control transistor T5 is electrically connected to a first power signal line VDD, and a second electrode of the first light-emitting control transistor T6 is electrically connected to the second node N2.

A control electrode of the second light-emitting control transistor T6 is electrically connected to both the first regulating unit M1 and the second regulating unit M2, a first electrode of the second light-emitting control transistor T6 is electrically connected to the third node N3, and a second electrode of the second light-emitting control transistor T6 is electrically connected to a fourth node N4. The fourth node N4 is also electrically connected to a light-emitting device E.

A control electrode of the first writing transistor T8 is electrically connected to a second reset signal line RST-B, a first electrode of the first writing transistor T8 is electrically connected to the data writing signal line Data, and a second electrode of the first writing transistor T8 is electrically connected to a fifth node N5.

A control electrode of the first regulating transistor T9 is electrically connected to the fifth node N5, and a first electrode of the first regulating transistor T9 is electrically connected to the enable signal line EM, and a second electrode of the first regulating transistor T9 is electrically connected to the control electrode of the second light-emitting control transistor T6.

A first plate of the first capacitor C1 is electrically connected to the first initialization signal line Vinit, and a second plate of the first capacitor C1 is electrically connected to the fifth node N5.

A control electrode of the second writing transistor T10 is electrically connected to the first reset signal line RST-A, a first electrode of the second writing transistor T10 is electrically connected to the data writing signal line Data, and a second electrode of the second writing transistor T10 is electrically connected to a sixth node.

A control electrode of the second regulating transistor T11 is electrically connected to the sixth node N6, a first electrode of the second regulating transistor T11 is electrically connected to a first regulating signal line Hf, and a second electrode of the second regulating transistor T11 is electrically connected to the control electrode of the second light-emitting control transistor T6.

A first plate of the second capacitor C2 is electrically connected to the first initialization signal line Vinit, and a second late of the second capacitor C2 is electrically connected to the sixth node N6.

The inventors have found that, the light-emitting driving circuit (e.g., the light-emitting driving circuit Q) in the light-emitting substrate 200 drives the light-emitting device E to emit light to provide a light source for the display apparatus 300, resulting in poor display quality of the display apparatus 300 when the display apparatus 300 displays an image, and the worse display quality when the display apparatus 300 is in the low grayscale state.

The inventors further discovered that this is because the multiple thin film transistors T in the light-emitting driving circuit Q adopt a top-gate structure. In a thin film transistor with a top gate structure, the channel is floating relative to the substrate, resulting in a floating body effect.

The description will be made by considering the driving transistor T3 of the multiple thin film transistors T in the light-emitting driving circuit Q as an example. When the light-emitting driving circuit Q is operating, the floating body effect of the driving transistor T3 will cause unstable driving current output by the light-emitting driving circuit Q to the light-emitting device E through the driving transistor T3, and will cause small potential difference of the control electrode of the driving transistor T3 under different driving currents. Based on this, the display quality of the display apparatus 300 will be affected caused by a fact that it will be impossible to accurately and effectively control turn-on or turn-off of the driving transistor T3.

Furthermore, the voltage value required for the control electrode of the driving transistor T3 when the display apparatus 300 (as shown in FIG. 1) is in a low grayscale state is less than the voltage value required for the control electrode of the driving transistor T3 when the display apparatus 300 is in a high grayscale state. Thus, when the display apparatus 300 is in a low grayscale state, the potential difference of the control electrode of the corresponding driving transistor T3 under different driving currents is small, making it more difficult to accurately and effectively control turn-on or turn-off of the driving transistor T3.

Based on this, it is possible to improve the structure of the thin film transistor T to ameliorate the floating body effect produced by the thin film transistor T, so as to realize precise control for the thin film transistor. The following description will be made by taking an example in which the thin film transistor T is the driving transistor T3.

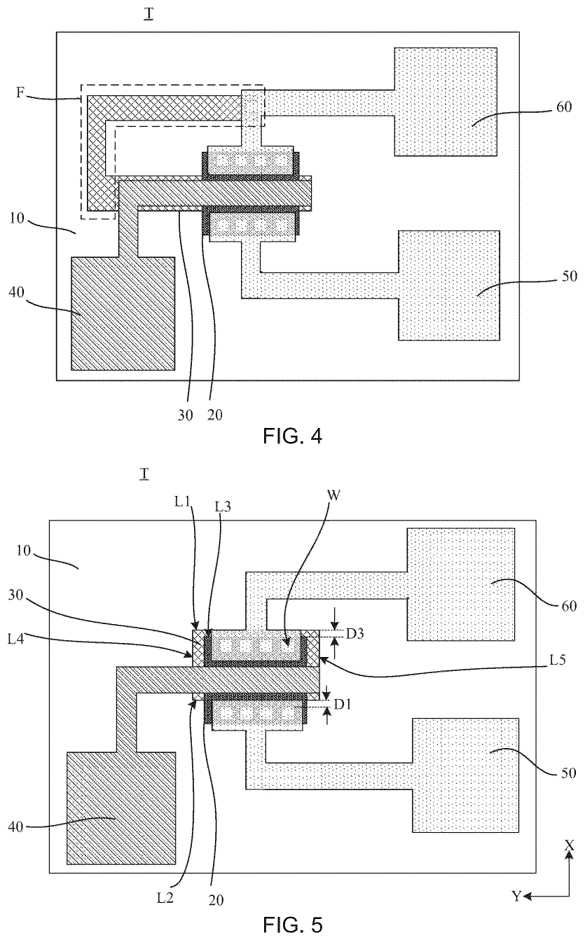

FIG. 4 is a structural diagram of a thin film transistor, in accordance with some implementions.

In some achievable implementions, referring to FIG. 4, the thin film transistor T includes a substrate 10, and an active layer 20, a first gate 30, a second gate 40, a first electrode 50, and a second electrode 60 that are formed on the substrate 10.

The first gate 30 and the second gate 40 are located on two sides of the active layer 20. An example in which the first gate 30 is a bottom-gate of the thin film transistor T and the second gate 40 is a top-gate of the thin film transistor T is used for description. Based on this, the first gate 30 is located between the active layer 20 and the substrate 10, and the second gate 40 is located on a side of the active layer 20 away from the first gate 30.

Of the first electrode 50 and the second electrode 60 of the thin film transistor T, one is the source of the thin film transistor T, and the other is the drain of the thin film transistor. The following description will be made by taking an example in which the first electrode 50 of the thin film transistor T is the drain of the thin film transistor T and the second electrode 60 of the thin film transistor T is the source of the thin film transistor T. The second electrode 60 of the thin film transistor T is configured to have a constant voltage potential.

The first gate 30 of the thin film transistor T is electrically connected to the second electrode 60 of the thin film transistor T, and the second electrode 60 of the thin film transistor T may be used to provide a constant voltage potential for the first gate 30 of the thin film transistor T, so that the first gate 30 of the thin film transistor T is kept at a fixed potential, so as to ameliorate the floating body effect of the thin film transistor T, which is beneficial to improving the performance of the thin film transistor. Furthermore, the driving current outputted from the light-emitting driving circuit Q to the light-emitting device E through the driving transistor T3 may be stably outputted, thereby improving the display quality of the display apparatus 300.

Furthermore, compared with a thin film transistor including only a second gate 40, for the thin film transistor T including the first gate 30 and the second gate 40, the first gate 30 of the thin film transistor T may be kept at a fixed potential, and the provision of the first gate 30 may increase the difficulty of controlling the channel of the thin film transistor T by the second gate 40. That is, the gate voltage value required when the thin film transistor T including the first gate 30 and the second gate 40 outputs the target current may be made greater than the gate voltage value required when the thin film transistor T including only the second gate 40 outputs the target current.

Therefore, the potential difference of the control electrode of the corresponding driving transistor T3 under different driving currents may be increased, which is conducive to realizing accurate and effective control for the turn-on or turn-off of the driving transistor T3.

The inventors further discovered that, in a case where the first gate 30 of the thin film transistor T is electrically connected to the second electrode 60 of the thin film transistor T, the active layer 20 is located between the first gate electrode 30 of the thin film transistor T and the second electrode 60 of the thin film transistor T. Based on this, a connection portion F is needed to be provided to avoid the active layer 20 to electrically connect the first gate 30 of the thin film transistor T and the second electrode 60 of the thin film transistor T.

However, the connection portion will increase the size of the thin film transistor T, which will affect the pixels per inch (PPI) of the display apparatus 300 and the display effect of the display apparatus 300 when the thin film transistor T is subsequently applied to a backlight module and a display apparatus 300.

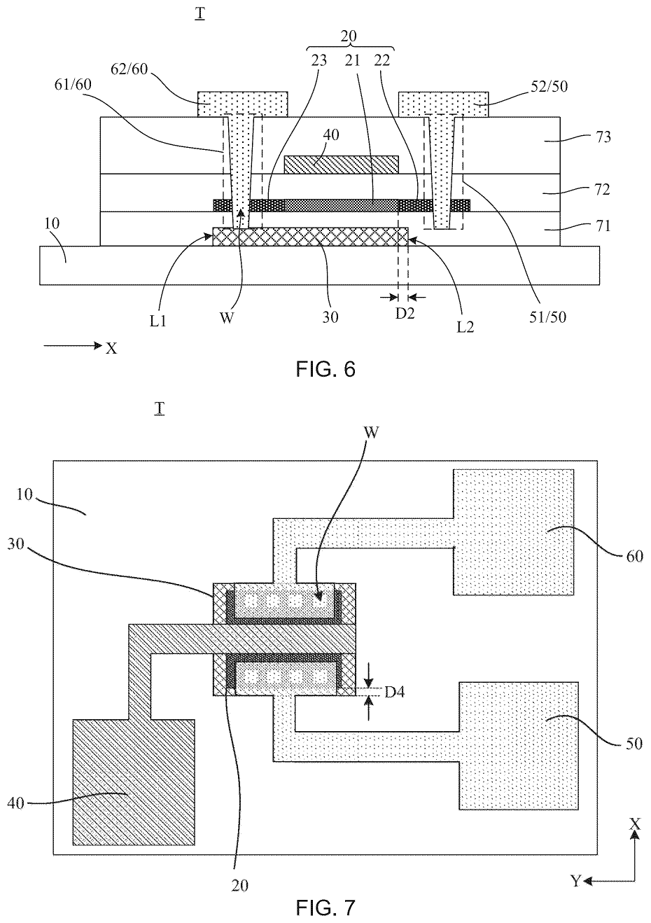

FIG. 5 is a structural diagram of a thin film transistor, in accordance with some embodiments; FIG. 6 is a diagram showing film layers of a thin film transistor, in accordance with some embodiments.

Based on the above, some embodiments of the present disclosure provide a thin film transistor T. Referring to FIGS. 5 and 6, the thin film transistor T includes a substrate 10, an active layer 20, a first gate 30, a second gate 40, a first electrode 50, and a second electrode 60.

In some examples, the substrate 10 may be a flexible substrate. For example, a material of the substrate 10 may be an organic material. For example, the material of the substrate 10 is any one of polyimide (PI), polycarbonate (PC) or polyvinyl chloride (PVC).

In some other examples, the substrate 10 may be a rigid substrate. For example, the rigid substrate may be a glass substrate or a polymethyl methacrylate (PMMA) substrate.

The active layer 20 is located on a side of the substrate 10. The active layer 20 includes a channel 21, and a first heavily doped region 22 and a second heavily doped region 23 that are located on two sides of the channel 21. The first heavily doped region 22 may be a source contact region, and the second heavily doped region 23 may be a drain contact region.

In some examples, a material of active layer 20 may include at least one of amorphous silicon, single crystal silicon, or polycrystalline silicon semiconductor materials. The following description will be made by taking an example in which the material of the active layer 20 is polycrystalline silicon.

In some examples, a thickness of the active layer 20 may be in a range of 100 Å to 1000 Å, inclusive. In a case where the thickness of the active layer 20 is in the above range, the subsequent crystallization treatment of the active layer 20 may be guaranteed to improve the conductivity of the channel 21 of the active layer 20 without increasing the difficulty of the manufacturing process.

In a case where the thickness of the active layer 20 is equal to or close to 100 Å, the thickness of the active layer 20 is relatively small, which may help reduce the difficulty of the process when forming the active layer 20, and may also ensure the subsequent crystallization treatment of the active layer 20 to improve the conductivity of the channel 21 of the active layer 20.

In a case where the thickness of the active layer 20 is equal to or close to 1000 Å, the thickness of the active layer 20 is relatively great, which may meet the requirements of the crystallization treatment of the active layer 20 well to help improve the conductivity of the channel 21 of the active layer 20, and may also meet the requirements of the corresponding manufacturing process of the existing active layer 20.

In some examples, the thickness of the active layer 20 may be in a range of 300 Å to 700 Å, inclusive. In some other examples, the thickness of the active layer 20 may be in a range of 100 Å to 800 Å, inclusive. In some other examples, the thickness of the active layer 20 may be in a range of 400 Å to 1000 Å, inclusive.

For example, the thickness of the active layer 20 is approximately any one of 100 Å, 200 Å, 300 Å, 400 Å, 500 Å, 600 Å, 700 Å, 800 Å, 900 Å, or 1000 Å, and the embodiments of the present disclosure are not limited thereto.

It will be noted that, the description will be made by taking an example in which the thickness of the active layer 20 is approximately 100 Å, due to certain uncontrollable errors (e.g., manufacturing process error, equipment accuracy, and measurement error), in a case where a floating range of an error of the thickness of the active layer 20 is within 10%×100 Å, it can be considered that the thickness of the active layer 20 is equal to 100 Å.

In addition, in some examples, due to certain uncontrollable errors (e.g., manufacturing process error, equipment accuracy, and measurement error), in a case where a floating range of an error of the thickness of the active layer 20 is within 5%×100 Å, it can be considered that the thickness of the active layer 20 is equal to 100 Å.

The first gate 30 is located on a side of the active layer 20 proximate to the substrate 10, and the second gate 40 is located on a side of the active layer 20 away from the first gate 30. An orthographic projection of the first gate 30 on the substrate 10 at least partially overlaps with an orthographic projection of the second heavily doped region 23 on the substrate 10. That is, the first gate 30 and the second gate 40 are respectively located on two sides of the active layer 20, and the first gate 30 is closer to the substrate 10 than the second gate 40. The first gate 30 may serve as the bottom gate of the thin film transistor T, and the second gate 40 may serve as the top gate of the thin film transistor T.

In some examples, a material of the first gate 30 includes conductive metal. The conductive metal includes at least one of aluminum, copper, or molybdenum, and the present disclosure is not limited thereto.

In some examples, a material of the second gate 40 may be the same as the material of the first gate 30. In some other examples, the material of the second gate 40 may be different from the material of the first gate 30. The embodiments of the present disclosure are not limited to the above examples.

In some examples, the thin film transistor T may further include a buffer layer Buffer, and the buffer layer is located between the substrate 10 and the first gate 30 and is used to play a supporting and buffering role.

In some examples, the thin film transistor T further includes a first gate insulating (GI) layer 71, and the first gate insulating layer 71 is located between the first gate 30 and the active layer 20, and the first gate insulating layer 71 insulates the first gate 30 from the active layer 20.

For example, a material of the first insulating layer includes any of inorganic insulating materials of silicon nitride, silicon oxynitride and silicon oxide. The material of the first insulating layer includes silicon dioxide, and the present disclosure is not limited thereto.

In some examples, the thin film transistor T further includes a second gate insulating (GI) layer 72, and the second gate insulating layer 72 is located between the active layer 20 and the second gate 40, and the second gate insulating layer 72 insulates the second gate 40 from the active layer 20.

For example, a material of the second insulating layer 72 includes any of inorganic insulating materials of silicon nitride, silicon oxynitride and silicon oxide. The material of the second insulating layer 72 may include silicon dioxide, and the present disclosure is not limited thereto.

The first electrode 50 and the second electrode 60 are both located on a side of the first gate 30 away from the substrate 10. Of the first electrode 50 and the second electrode 60, one is the source of the thin film transistor T, and the other is the drain of the thin film transistor. The following description will be made by taking an example in which the first electrode 50 of the thin film transistor T is the drain of the thin film transistor T and the second electrode 60 of the thin film transistor T is the source of the thin film transistor T. The second electrode 60 of the thin film transistor T is configured to have a constant voltage potential.

The first electrode 50 of the thin film transistor T includes a first via connection portion 51 and a main portion (which may be also referred to as a first main portion for the convenience of description) 52. The main portion 52 is located on a side of the first gate 30 away from the substrate 10. The first via connection portion 51 is located between the main portion 52 of the first electrode 50 and the first gate 30. The first via connection portion 51 is used to electrically connect the main portion 52 of the first electrode 50 and the first heavily doped region 22. That is, the first electrode 50 is electrically connected to the first heavily doped region 22 of the active layer 20 by using the first via connection portion 51.

The second electrode 60 of the thin film transistor T includes a second via connection portion 61 and a main portion 62 (which may be also referred to as a second main portion for the convenience of description). The second via connection portion 61 is located between the main portion 62 of the second electrode 60 and the first gate 30, and an orthographic projection of the second via connection portion 61 on the substrate 10 is located within an orthographic projection of the second heavily doped region 23 on the substrate 10. The main portion 62 may be electrically connected to the second heavily doped region 23 through the second via connection portion 61, and the main portion 62 may also be electrically connected to the first gate 30 through the second via connection portion 61. That is, the second electrode 60 may be electrically connected to both the second heavily doped region 23 and the first gate 30 by using the second via connection portion 61. The second electrode 60 of the thin film transistor T is configured to have a constant voltage potential.

Based on this, the second electrode 60 of the thin film transistor T may be used to provide a constant voltage potential for the first gate 30 of the thin film transistor T, so that the first gate 30 of the thin film transistor T maintains a fixed potential to ameliorate the floating body effect of the thin film transistor T, which is beneficial to improving the performance of the thin film transistor. As a result, the driving current outputted from the light-emitting driving circuit Q to the light-emitting device E via the driving transistor T3 may be stably outputted, thereby improving the display quality of the display apparatus 300.

In addition, since the second electrode 60 may be electrically connected to both the second heavily doped region 23 and the first gate 30 by using the second via connection portion 61, the second via connection portion 61 originally existing in the thin film transistor T for electrically connecting the second electrode 60 and the second heavily doped region 23 may be used to electrically connect the second electrode 60 and the first gate 30. Based on this, there is no need to additionally provide a connection portion that needs to avoid the active layer 20 of the thin film transistor T, thereby ameliorating the problem of the size of the thin film transistor T being increased due to the connection portion. Furthermore, the orthographic projection of the second via connection portion 61 on the substrate 10 is set to be within the orthographic projection of the second heavily doped region 23 on the substrate 10. The longitudinal space between the main portion 62 and the first gate 30 may be fully utilized, i.e., the internal space of the thin film transistor T may be fully utilized, so that there is no need to increase the size of the thin film transistor T. In a case where the thin film transistor is subsequently applied to the light-emitting driving circuit Q, it will not be limited by the area and size, which will not affect the pixels per inch of the display apparatus 300.

In some examples, the thin film transistor T further includes an inter-layer dielectric (ILD) layer 73. The inter-layer dielectric layer 73 is located between the second gate 40 and the first main portion 52 of the first electrode 50 and second main portion 62 of the second electrode 60. The interlayer dielectric layer 73 insulates the second gate 40 from the first main portion 52 of the first electrode 50 and the second main portion 62 of the second electrode 60. For example, the inter-layer dielectric layer 73 is made of silicon oxidean (SiOx), and the embodiments of the present disclosure are not limited thereto.

It will be noted that the main portion 52 of the first electrode 50 and the main portion 62 of the second electrode 60 are located on a side of the first gate 30 away from the substrate 10. The first via connection portion 51 may be a structure formed between the main portion 52 of the first electrode 50 and the first gate 30 when the first electrode 50 of the thin film transistor T is formed, and the second via connection portion 61 may be a structure formed between the main portion 52 of the second electrode 60 and the first gate 30 when the second electrode 60 of the thin film transistor T is formed. The first via connection portion 51 and the second via connection portion 61 also need to penetrate the inter-layer dielectric layer 73.

To sum up, for the thin film transistor T provided in the embodiments of the present disclosure, the orthographic projection of the first gate 30 on the substrate 10 at least partially overlaps with the orthographic projection of the second heavily doped region 23 on the substrate 10, and the orthographic projection of the second via connection portion 61 on the substrate 10 is located within the orthographic projection of the second heavily doped region 23 on the substrate 10. Thus, it may be possible to not only achieve that the main portion 62 of the second electrode 60 is electrically connected to both the second heavily doped region 23 and the first gate 30 through the second via connection portion 61, but also ameliorate the problem of increasing the size of the thin film transistor T due to the additional provision of the second via connection portion 61 of the second electrode 60. That is, for the thin film transistor T provided in the embodiments of the present disclosure, it may be possible to ameliorate the floating body effect of the thin film transistor T without changing the size of the thin film transistor T as much as possible, so as to improve the display quality of the display apparatus 300 while ensuring the pixels per inch of the display apparatus 300.

The description of “the second via connection portion 61 is electrically connected to the first gate 30” may include two situations.

First situation: the second via connection portion 61 is directly electrically connected to the first gate 30.

Second situation: the second via connection portion 61 is electrically connected to the first gate 30 indirectly.

The manner in which the second via connection portion 61 is electrically connected to the first gate 30 in the embodiments of the present disclosure is not limited to the above. The above two types of connection manners will be described in detail below with reference to the accompanying drawings. However, no matter the second via connection portion 61 is electrically connected to the first gate electrode 30 directly or indirectly, it is possible to achieve that the first gate 30 of the thin film transistor T is electrically connected to the second electrode 60 of the thin film transistor T. First, the first connection manner will be introduced below in conjunction with relevant drawings.

In some embodiments, as shown in FIGS. 5 and 6, the second heavily doped region 23 includes at least one via hole W, an end of the second via connection portion 61 is electrically connected to the second main portion 62 of the second electrode 60, and the other end of the second via connection portion 61 penetrates the via hole(s) W to be electrically connected to the first gate 30.

Based on this, when forming the second electrode 60, the via hole(s) W of the second heavily doped region 23 are filled with the other end of the second via connection portion 61, and the other end of the second via connection portion 61 penetrates the via hole(s) W of the second heavily doped region 23 and extends to be electrically connected to the first gate 30 at a lower position, so that the second via connection portion 61 is used to electrically connect both the second heavily doped region 23 and the first gate 30. Thus, there is no need to additionally provide a connection portion that needs to avoid the active layer 20 of the thin film transistor T, which may ameliorate the problem of the size of the thin film transistor T being increased due to the connection portion. Moreover, since the thin film transistor T is electrically connected to the second heavily doped region 23 and the first gate 30 by extending the second via connection portion 61, there is no need to increase the manufacturing process of the thin film transistor T.

In addition, by forming a via hole in the second heavily doped region 23 of the thin film transistor T, the second via connection portion 61 is electrically connected to the first gate 30 through the second heavily doped region 23, so that the longitudinal space between the second heavily doped region 23 and the first gate 30 is fully utilized, i.e., the internal space of the thin film transistor T is fully utilized, so that the size of the thin film transistor T will not be increased. In a case where the thin film transistor T is subsequently applied to the light-emitting driving circuit Q, it will not be limited by the area and size, so that the pixels per inch of the display apparatus 300 will not be affected.

In some examples, the second heavily doped region 23 may include one via hole W. In this case, an end of the second via connection portion 61 is electrically connected to the second main portion 62 of the second electrode 60, and the via hole W is filled with the other end of the second via connection portion 61, and the other end of the second via connection portion 61 penetrates the via hole W to be electrically connected to the first gate 30.

In some examples, the second heavily doped region 23 may include a plurality of via holes W. An orthographic projection of the second main portion 62 of the second electrode 60 on the active layer 20 covers all the via holes W in the second heavily doped region 23. The second via connection portion 61 may include a plurality of sub-portions that are in one-to-one correspondence with the plurality of via holes W. A via hole W is filled with a sub-portion of the second via connection portion 61, and the sub-portion of the second via connection portion 61 penetrates the via hole to be electrically connected to the first gate 30.

For example, FIG. 5 is illustrated by taking an example in which the second heavily doped region 23 includes four via holes W. However, the number of via holes W in the second heavily doped region 23 is not limited in the embodiments of the present disclosure.

In some embodiments, as shown in FIGS. 5 and 6, the first gate 30 of the thin film transistor T is electrically connected to the second electrode 60 of the thin film transistor T. Therefore, an orthographic projection of the first gate 30 on the substrate 10 is set to be non-overlapping with an orthographic projection of the first via connection portion 51 (the via hole W provided in the first heavily doped region 22) on the substrate 10, which is equivalent to that the orthographic projection of the first gate 30 on the substrate 10 is non-overlapping with an orthographic projection of the second via connection portion 61 on the substrate 10.

Based on this, there may be a spacing between the orthographic projection of the first gate 30 on the substrate 10 and the orthographic projection of the first via connection portion 51 on the substrate 10, which prevents short-circuit from occurring between the first electrode 50 and the second electrode 60 of the thin film transistor T caused by the short-circuit between the first via connection portion 51 of the first electrode 50 and the first gate 30, thereby ensuring the performance of the thin film transistor T.

In some embodiments, referring to FIGS. 5 and 6, on the basis of setting the orthographic projection of the first gate 30 on the substrate 10 to be non-overlapping with the orthographic projection of the via hole W provided in the first heavily doped region 22 on the substrate 10, a minimum spacing D1 between the orthographic projection of the first gate 30 on the substrate 10 and the orthographic projection of the via hole W on the substrate 10 may be set to be greater than or equal to 0.5 μm.

With the above structure, a minimum spacing D1 may be provided between the orthographic projection of the first gate 30 on the substrate 10 and the orthographic projection of the first via connection portion 51 on the substrate 10, which prevents short-circuit from occurring between the first electrode 50 and the second electrode 60 of the thin film transistor T caused by the short-circuit between the first via connection portion 51 of the first electrode 50 and the first gate 30, thereby ensuring the performance of the thin film transistor T.

In some examples, as shown in FIGS. 5 and 6, in a first direction X, the first gate 30 includes a first side L1 and a second side L2 that are oppositely disposed, and the first side L1 is located on a side of the second side L2 away from the first via connection portion 51. The first direction X is a direction from the first electrode 50 to the second electrode 60.

The minimum spacing D1 between the orthographic projection of the first gate 30 on the substrate 10 and the orthographic projection of the via hole W provided in the first heavily doped region 22 on the substrate 10 is set to be greater than or equal to 0.5 μm, which is equivalent to that the minimum spacing D1 between an orthographic projection of the second side L2 of the first gate 30 on the substrate 10 and the orthographic projection of the via hole W provided in the first heavily doped region 22 on the substrate 10 is set to be greater than or equal to 0.5 μm.

In a case where the minimum spacing D1 between the orthographic projection of the second side L2 of the first gate 30 on the substrate 10 and the orthographic projection of the via hole W provided in the first heavily doped region 22 on the substrate 10 is equal to or close to 0.5 μm, the short-circuit is prevented from occurring between the first electrode 50 and the second electrode 60 of the thin film transistor T caused by the short-circuit between the first via connection portion 51 of the first electrode 50 and the first gate 30.

Furthermore, in a case where the minimum spacing D1 between the orthographic projection of the second side L2 of the first gate 30 on the substrate 10 and the orthographic projection of the via hole W provided in the first heavily doped region 22 on the substrate 10 is equal to or close to 0.5 μm, the minimum spacing D1 is small, so that the minimum spacing between the orthographic projection of the second side L2 of the first gate 30 on the substrate 10 and an orthographic projection of the channel 21 of the active layer 20 on the substrate 10 may be made great. That is, the first gate 30 may extend in the first direction X to the outside of the channel of the active layer 20. Based on this, the problem of uneven of the active layer 20 caused by the first gate 30 may be prevented, which may prevent the problem that imperfect polysilicon is generated in the active layer during the crystallization process, so as to improve the conductivity of the channel 21 of the active layer 20.

In some embodiments, referring to FIGS. 5 and 6, on the basis of setting the orthographic projection of the first gate 30 on the substrate 10 to be non-overlapping with the orthographic projection of the via hole W provided in the first heavily doped region 22 on the substrate 10, the minimum spacing D1 between the orthographic projection of the first gate 30 on the substrate 10 and the orthographic projection of the via hole W provided in the first heavily doped region 22 on the substrate 10 may be set to be less than or equal to 5 μm.

With the above structure, there may be a minimum spacing D1 between the orthographic projection of the first gate 30 on the substrate 10 and the orthographic projection of the first via connection portion 51 on the substrate 10, and the minimum spacing D1 is relatively great. Therefore, it is possible to prevent short-circuit well from occurring between the first electrode 50 and the second electrode 60 of the thin film transistor T caused by short-circuit between the first via connection portion 51 of the first electrode 50 and the first gate 30, thereby ensuring the performance of the thin film transistor T.

In some examples, referring to FIGS. 5 and 6, the minimum spacing D1 between the orthographic projection of the first gate 30 on the substrate 10 and the orthographic projection of the via hole W provided in the first heavily doped region 22 on the substrate 10 is less than or equal to 5 μm, which is equivalent to setting the minimum spacing D1 between the orthographic projection of the second side L2 of the first gate 30 on the substrate 10 and the orthographic projection of the via hole W provided in the first heavily doped region 22 on the substrate 10 to be less than or equal to 5 μm.

In a case where the minimum spacing D1 between the orthographic projection of the second side L2 of the first gate 30 on the substrate 10 and the orthographic projection of the via hole W provided in the first heavily doped region 22 on the substrate 10 is equal to or close to 5 μm, the minimum spacing D1 may be made great, thereby preventing short-circuit well from occurring between the first electrode 50 and the second electrode 60 of the thin film transistor T caused by short-circuit between the first via connection portion 51 of the first electrode 50 and the first gate 30.

Furthermore, since the minimum spacing D1 between the orthographic projection of the second side L2 of the first gate 30 on the substrate 10 and the orthographic projection of the via hole W provided in the first heavily doped region 22 on the substrate 10 is equal to or close to 5 μm, the minimum spacing D1 will not be too great. Therefore, there will be a gap between the orthographic projection of the second side L2 of the first gate 30 on the substrate 10 and the orthographic projection of the channel 21 of the active layer 20 on the substrate 10. That is, the first gate 30 may extend in the first direction X to the outside of the channel of the active layer 20. Based on this, the problem of uneven of the active layer 20 caused by the first gate 30 may be prevented, which may prevent the problem that imperfect polysilicon is generated in the active layer during the crystallization process, so as to improve the conductivity of the channel 21 of the active layer 20.

In some embodiments, referring to FIGS. 5 and 6, the minimum spacing D1 between the orthographic projection of the first gate 30 on the substrate 10 and the orthographic projection of the via hole W provided in the first heavily doped region 22 on the substrate 10 is in a range of 0.5 μm to 5 μm, inclusive. Based on this, a gap may be provided between the orthographic projection of the second side L2 of the first gate 30 on the substrate 10 and the orthographic projection of the via hole W provided in the first heavily doped region 22 on the substrate 10, thereby preventing short-circuit between the first via connection portion 51 of the first electrode 50 and the first electrode 30; and moreover, a gap may be provided between the orthographic projection of the second side L2 of the first gate 30 on the substrate 10 and the orthographic projection of the channel 21 of the active layer 20 on the substrate 10, thereby preventing the problem of uneven of the active layer 20 caused by the first gate 30.

In some other embodiments, the minimum spacing D1 between the orthographic projection of the first gate 30 on the substrate 10 and the orthographic projection of the via hole W provided in the first heavily doped region 22 on the substrate 10 may be in a range of 0.5 μm to 3 μm, inclusive. In some other embodiments, the minimum spacing D1 between the orthographic projection of the first gate 30 on the substrate 10 and the orthographic projection of the via hole W provided in the first heavily doped region 22 on the substrate 10 may be in a range of 0.5 μm to 2 μm, inclusive.

In some examples, the minimum spacing D1 between the orthographic projection of the first gate 30 on the substrate 10 and the orthographic projection of the via hole W provided in the first heavily doped region 22 on the substrate 10 may be any one of approximately 0.5 μm, 0.8 μm, 1 μm, 1.5 μm, 2 μm, 3 μm, 4 μm or 5 μm, and the embodiments of the present disclosure are not limited thereto.

It will be noted that, the description will be made by taking an example in which the minimum spacing D1 between the orthographic projection of the first gate 30 on the substrate 10 and the orthographic projection of the via hole W provided in the first heavily doped region 22 on the substrate 10 is approximately 0.5 μm, due to certain uncontrollable errors (e.g., manufacturing process errors, equipment accuracy, and measurement errors), in a case where the error floating range of the minimum spacing D1 floats within the range of 10%×0.5 μm, it can also be considered that the minimum spacing D1 is equal to 0.5 μm.

In addition, in some examples, due to certain uncontrollable errors (e.g., manufacturing process errors, equipment accuracy, and measurement errors), in a case where the error floating range of the minimum spacing D1 floats within the range of 5%×0.5 μm, it can also be considered that the minimum spacing D1 is equal to 0.5 μm.

In some examples, referring to FIGS. 5 and 6, the first gate 30 of the thin film transistor T is disposed on a side of the active layer 20 proximate to the substrate 10. Furthermore, when manufacturing the thin film transistor T, the first gate 30 is first formed on the substrate 10, and then the active layer 20 is formed. When forming the active layer 20, an amorphous silicon layer needs to be formed on the side of the first gate 30 away from the substrate 10, that is, an amorphous silicon layer needs to be formed on a side of the first gate insulating layer 71 away from the substrate 10; and then, an excimer laser annealing (ELA) process is performed on the amorphous silicon layer to form an active layer 20 including polycrystalline silicon.

In the embodiments of the present disclosure, the orthographic projection of the channel 21 of the thin film transistor T on the substrate 10 may be set to be within the orthographic projection of the first gate 30 on the substrate 10.

Since the first heavily doped region 22 and the second heavily doped region 23 of the active layer 20 are formed by conductorization, when the first heavily doped region 22 and the second heavily doped region 23 of the active layer 20 are formed on an uneven surface, the impact on the performance of the first heavily doped region 22 and the second heavily doped region 23 of the active layer 20 is small.

Based on this, the orthographic projection of the channel 21 of the thin film transistor T on the substrate 10 may be set to be within the orthographic projection of the first gate 30 on the substrate 10. Thus, the step region formed at the edge of the first gate 30 may be made to avoid the channel 21 of the active layer 20 to prevent the channel 21 of the active layer 20 from being formed on an uneven surface to ensure the conductivity of the channel 21 of the active layer 20.

In some embodiments, referring to FIGS. 5 and 6, based on the fact that the orthographic projection of the channel 21 of the thin film transistor T on the substrate 10 is located within the orthographic projection of the first gate 30 of the thin film transistor T on the substrate 10, a minimum spacing D2 between an outer edge of the orthographic projection of the first gate 30 on the substrate 10 and an outer edge of the orthographic projection of the channel 21 on the substrate 10 is set to be greater than or equal to 0.5 μm.

In the case where the minimum spacing D2 between the outer edge of the orthographic projection of the first gate 30 on the substrate 10 and the outer edge of the orthographic projection of the channel 21 on the substrate 10 is equal to or close to 0.5 μm, the first gate 30 may be expanded outside so that the step region formed at the edge of the first gate 30 avoids the channel 21 of the active layer 20 to prevent the channel 21 of the active layer 20 from being formed on an uneven surface to ensure the conductivity of the channel 21 of the active layer 20.

In some other embodiments, the minimum spacing D2 between the outer edge of the orthographic projection of the first gate 30 on the substrate 10 and the outer edge of the orthographic projection of the channel 21 on the substrate 10 is greater than or equal to 5 μm.

In the case where the minimum spacing D2 between the outer edge of the orthographic projection of the first gate 30 on the substrate 10 and the outer edge of the orthographic projection of the channel 21 on the substrate 10 is equal to or close to 5 μm, the first gate 30 may be expanded outside to a greater extent, so that the step region formed at the edge of the first gate 30 may avoid the channel 21 of the active layer 20 well, so as to prevent the channel 21 of the active layer 20 from being formed on an uneven surface, so as to ensure the conductivity of the channel 21 of the active layer 20.

For example, the minimum spacing D2 between the outer edge of the orthographic projection of the first gate 30 on the substrate 10 and the outer edge of the orthographic projection of the channel 21 on the substrate 10 is any one of approximately 0.5 μm, 1 μm or 2 μm, and the embodiments of the present disclosure are not limited thereto.

It will be noted that, the description will be made by taking an example in which the minimum spacing D2 between the outer edge of the orthographic projection of the first gate 30 on the substrate 10 and the outer edge of the orthographic projection of the channel 21 on the substrate 10 is approximately 0.5 μm, due to certain uncontrollable errors (e.g., manufacturing process errors, equipment accuracy, measurement errors, etc.), in a case where the error floating range of the minimum spacing D2 floats within the range of 10%×0.5μm, it may also be considered that the minimum spacing D2 is equal to 0.5 μm.

In addition, in some examples, due to certain uncontrollable errors (e.g., manufacturing process errors, equipment accuracy, measurement errors), in a case where the error floating range of the minimum spacing D2 floats within the range of 5%×0.5μm, it may be considered that the minimum spacing D2 is equal to 0.5 μm.

It will be noted that, since the first gate 30 includes a first side L1 and a second side L2, and the second side L2 is closer to the first via connection portion 51 than the first side L1. In order to prevent short-circuit between the first gate 30 and the first electrode 50, it is necessary to set a minimum spacing D1 between the first gate 30 and the first via connection portion 51 (the via hole W provided in the first heavily doped region 22) (which has been described in the above embodiments and will not be repeated here). Based on this, the second side L2 of the first gate 30 needs to consider the expansion range to ensure that the minimum spacing D1 is reserved.

The extent of the extension of the first side L1 of the first gate 30 will be described in detail below with reference to the accompanying drawings.

In the above embodiments, it is introduced that “the orthographic projection of the first gate 30 on the substrate 10 at least partially overlaps with the orthographic projection of the second heavily doped region 23 on the substrate 10”, so that the second via connection portion 61 is electrically connected to both the second heavily doped region 23 and the first gate 30.

The description of “the orthographic projection of the first gate 30 on the substrate 10 at least partially overlaps with the orthographic projection of the second heavily doped region 23 on the substrate 10” includes the following cases.
First case: the orthographic projection of the first gate 30 on the substrate 10 partially overlaps with the orthographic projection of the second heavily doped region 23 on the substrate 10, which is equivalent to that the first side L1 of the first gate 30 extends outside to satisfy the orthographic projection of the first side L1 of the first gate 30 on the substrate 10 overlapping with the orthographic projection of the second heavily doped region 23 on the substrate 10. Thus, the step region formed at the edge of the first gate 30 (the first side L1) may avoid the channel 21 of the active layer 20 to prevent the channel 21 of the active layer 20 from being formed on an uneven surface, thereby ensuring the conductivity of the channel 21 of the active layer 20.
Second case: the orthographic projection of the second heavily doped region 23 on the substrate 10 is located within the orthographic projection of the first gate 30 on the substrate 10, which is equivalent to that the first side L1 of the first gate 30 extends to satisfy the orthographic projection of the first side L1 of the first gate 30 on the substrate 10 coinciding with an orthographic projection of an edge of the second heavily doped region 23 away from the first heavily doped region 22 on the substrate 10, or that the first side L1 of the first gate 30 extends to the outside of the second heavily doped region 23, so that the step region formed at the edge of the first gate 30 (the first side L1) may avoid the second heavily doped region 23 and the channel 21 of the active layer 20, so as to prevent the second heavily doped region 23 and the channel 21 of the active layer 20 from being formed on an uneven surface to ensure the performance of the active layer 20.

In some embodiments, referring to FIGS. 5 and 6, for case of “the first side L1 of the first gate 30 extends to the outside of the second heavily doped region 23”, a minimum spacing D3 between an orthographic projection of the first side L1 of the first gate 30 on the substrate 10 and an orthographic projection of the third side L3, away from the first heavily doped region 22, of the second heavily doped region 23 on the substrate 10 may be set to be greater than or equal to 0.5 μm.

In the case where the minimum spacing D3 between the orthographic projection of the second side L2 of the first gate 30 on the substrate 10 and the orthographic projection of the third side L3, away from the first heavily doped region 22, of the second heavily doped region 23 on the substrate 10 is equal to or close to 0.5 μm, the step region formed at the edge of the first gate 30 (the first side L1) may avoid the second heavily doped region 23 and the channel 21 of the active layer 20 to prevent the second heavily doped region 23 and the channel 21 of the active layer 20 from being formed on an uneven surface, so as to ensure the performance of the active layer 20. Moreover, in this case, the second side L2 of the first gate 30 extends outside to a small extent, which is equivalent to not increasing the size of the thin film transistor T. Thus, in a case where the thin film transistor T is subsequently applied to the light-emitting driving circuit Q, it will not be limited by the area and size, so that the pixels per inch of the display apparatus 300 will not be affected.

In some embodiments, referring to FIGS. 5 and 6, the minimum spacing D3 between the orthographic projection of the first side L1 of the first gate 30 on the substrate 10 and the orthographic projection of the third side L3, away from the first heavily doped region 22, of the second heavily doped region 23 on the substrate 10 is less than or equal to 10 μm.

In the case where the minimum spacing D3 between the orthographic projection of the first side L1 of the first gate 30 on the substrate 10 and the orthographic projection of the third side L3, away from the first heavily doped region 22, of the second heavily doped region 23 on the substrate 10 is equal to or close to 10 μm, the first side L1 of the first gate 30 may extend outside to a great extent, but the size of the thin film transistor T will not be greatly increased. In this case, the step region formed at the edge of the first gate 30 (the first side L1) may avoid the second heavily doped region 23 and the channel 21 of the active layer 20 well to prevent the second heavily doped region 23 and the channel 21 of the active layer 20 from being formed on an uneven surface to ensure the performance of the active layer 20.

In some embodiments, referring to FIGS. 5 and 6, the minimum spacing D3 between the orthographic projection of the first side L1 of the first gate 30 on the substrate 10 and the orthographic projection of the third side L3, away from the first heavily doped region 22, of the second heavily doped region 23 on the substrate 10 is in a range of 0.5 μm to 10 μm, inclusive.

Based on this, the step region formed at the edge of the first gate 30 (the first side L1) may avoid the second heavily doped region 23 and the channel 21 of the active layer 20, which may prevent the second heavily doped region 23 and the channel 21 of the active layer 20 from being formed on the uneven surface to ensure the performance of the active layer 20, and may prevent affecting the size of the thin film transistor T due to the excessive outward extension of the first side L1 of the first gate 30.

In some other embodiments, the minimum spacing D3 between the orthographic projection of the first side L1 of the first gate 30 on the substrate 10 and the orthographic projection of the third side L3, away from the first heavily doped region 22, of the second heavily doped region 23 on the substrate 10 is in a range of 0.5 μm to 5 μm, inclusive. In some other embodiments, the minimum spacing D3 between the orthographic projection of the first side L1 of the first gate 30 on the substrate 10 and the orthographic projection of the third side L3, away from the first heavily doped region 22, of the second heavily doped region 23 on the substrate 10 is in a range of 0.5 μm to 3 μm, inclusive.

For example, the minimum spacing D3 between the orthographic projection of the first side L1 of the first gate 30 on the substrate 10 and the orthographic projection of the third side L3, away from the first heavily doped region 22, of the second heavily doped region 23 on the substrate 10 is any one of approximately 0.5 μm, 1 μm, 2 μm, 3 μm, 5 μm, 7 μm or 10 μm, and the embodiments of the present disclosure are not limited thereto.

It will be noted that, the description will be made by taking an example in which the minimum spacing D3 between the orthographic projection of the first side L1 of the first gate 30 on the substrate 10 and the orthographic projection of the third side L3, away from the first heavily doped region 22, of the second heavily doped region 23 on the substrate 10 is approximately 0.5 μm, due to certain uncontrollable errors (e.g., manufacturing process errors, equipment accuracy, and measurement errors), in a case where the error floating range of the minimum spacing D3 floats within the range of 10%×0.5 μm, it may also be considered that the minimum spacing D3 is equal to 0.5 μm.

In addition, in some examples, due to certain uncontrollable errors (e.g., manufacturing process errors, equipment accuracy, and measurement errors), in a case where the error floating range of the minimum spacing D3 floats within the range of 5%×0.5 μm, it may be considered that the minimum spacing D3 is equal to 0.5 μm.

In some embodiments, as shown in FIG. 5, the first gate 30 further includes a fourth side L4 and a fifth side L5 that are oppositely disposed in a second direction Y. An end of the fourth side L4 is electrically connected to the first side L1, and the other end of the fourth side L4 is electrically connected to the second side L2; an end of the fifth side L5 is electrically connected to the first side L1, and the other end of the fifth side L5 is electrically connected to the second side L2.

In some examples, for the above-mentioned case of “the first side L1 of the first gate 30 extends to the outside of the second heavily doped region 23”, a spacing between an orthographic projection of the fourth side L4 on the substrate 10 and the orthographic projection of the second heavily doped region 23 on the substrate 10 is greater than or equal to 0.5 μm.

Based on this, the step region formed at the edge of the first gate 30 (the fourth side L4) may avoid the second heavily doped region 23 and the channel 21 of the active layer 20 well to prevent the second heavily doped region 23 and the channel 21 of the active layer 20 from being formed on the uneven surface to ensure the performance of the active layer 20; in addition, it may also prevent the size of the thin film transistor T from being affected due to the excessive outward extension of the fourth side L4 of the first gate 30 extends outside too much.

In some examples, for the above-mentioned case of “the first side L1 of the first gate 30 extends to the outside of the second heavily doped region 23”, a spacing between an orthographic projection of the fifth side L5 on the substrate 10 and the orthographic projection of the second heavily doped region 23 on the substrate 10 is greater than or equal to 0.5 μm.

Based on this, the step region formed at the edge of the first gate 30 (the fifth side L5) may avoid the second heavily doped region 23 and the channel 21 in the active layer 20 well to prevent the second heavily doped region 23 and the channel 21 of the active layer 20 from being formed on an uneven surface to ensure the performance of the active layer 20; and in addition, it may also prevent the size of the thin film transistor T from being affected due to the excessive outward extension of the fifth side L5 of the first gate 30.

It will be noted that, for the definition of the spacing between the orthographic projection of the fourth side L4 or fifth side L5 on the substrate 10 and the orthographic projection of the second heavily doped region 23 on the substrate 10, reference may be made to the definition of the spacing between the orthographic projection of the first side L1 on the substrate 10 and the orthographic projection of the second heavily doped region 23 on the substrate 10, which will not be repeated here.

The above mainly introduces the situation that the second via connection portion 61 is directly electrically connected to the first gate 30 in combination with the relevant drawings. The following will mainly introduce the second connection manner between the second via connection portion 61 and the first gate 30 in combination with the relevant drawings: the second via connection portion 61 being indirectly electrically connected to the first gate 30.

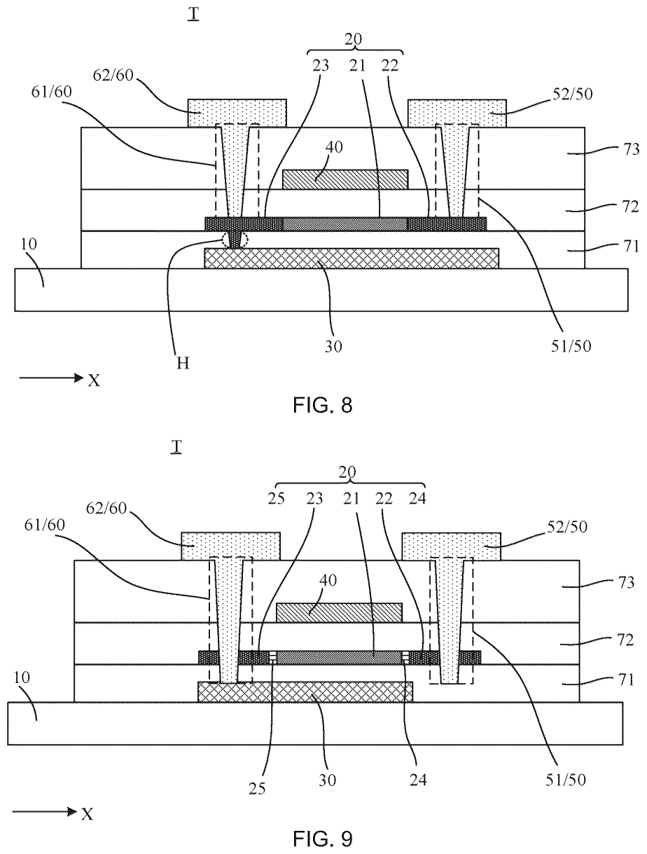

FIG. 7 is a structural diagram of a thin film transistor, in accordance with some other embodiments, and FIG. 8 is a diagram showing film layers of a thin film transistor, in accordance with some other embodiments.

In some embodiments, as shown in FIGS. 7 and 8, an end of the second via connection portion 61 is electrically connected to the second main portion 62 of the second electrode 60, and the other end of the second via connection portion 61 is electrically connected to the first gate 30 through the second heavily doped region 23.

The second heavily doped region 23 may include a third via connection portion H. The third via connection portion H penetrates the first gate insulating layer 71 to cause the second heavily doped region 23 to be electrically connected to the first gate 30. Furthermore, the second electrode 60 may be electrically connected to the first gate 30 through the second via connection portion 61 and the second heavily doped region 23 in sequence. That is, the second electrode 60 may be indirectly electrically connected to the first gate 30 by using the second via connection portion 61.

Based on this, there is no need to additionally provide a connection portion that needs to avoid the active layer 20 of the thin film transistor T, so that the problem of the size of the thin film transistor T being increased due to the connection portion is ameliorated. Furthermore, the longitudinal space between the second heavily doped region 23 and the first gate 30 may be fully utilized, i.e., the internal space of the thin film transistor T may be fully utilized, so that the size of the thin film transistor T will not be increased. In a case where the thin film transistor T is subsequently applied to the light-emitting driving circuit Q, it will not be limited by the area and size, which will not affect the pixels per inch of the display apparatus 300.

In some embodiments, referring to FIGS. 7 and 8, the first gate 30 of the thin film transistor T is disposed on a side of the active layer 20 proximate to the substrate 10. Thus, when manufacturing the thin film transistor T, the first gate 30 is first formed on the substrate 10, and then the active layer 20 is formed. When the active layer 20 is formed, an amorphous silicon layer needs to be formed on the side of the first gate 30 away from the substrate 10, i.e., an amorphous silicon layer is formed on the side of the first gate insulating layer 71 away from the substrate 10; and then an excimer laser annealing process is performed on the amorphous silicon layer to form an active layer 20 of In the embodiments of the present disclosure, the orthographic projection of the channel 21 of the thin film transistor T on the substrate 10 may be set to be within the orthographic projection of the first gate 30 on the substrate 10.

Since the first heavily doped region 22 and the second heavily doped region 23 of the active layer 20 are formed by conductorization, when the first heavily doped region 22 and the second heavily doped region 23 of the active layer 20 are formed on an uneven surface, the impact on the performance of the first heavily doped region 22 and the second heavily doped region 23 of the active layer 20 is small.

Based on this, the orthographic projection of the channel 21 of the thin film transistor T on the substrate 10 may be set to be within the orthographic projection of the first gate 30 on the substrate 10. Thus, the step region formed at the edge of the first gate 30 may be made to avoid the channel 21 of the active layer 20 to prevent the channel 21 of the active layer 20 from being formed on an uneven surface to ensure the conductivity of the channel 21 of the active layer 20.

In some embodiments, referring to FIGS. 7 and 8, on the basis of the orthographic projection of the channel 21 of the thin film transistor T on the substrate 10 being located within the orthographic projection of the first gate 30 on the substrate 10, the minimum spacing between the outer edge of the orthographic projection of the first gate 30 on the substrate 10 and the outer edge of the orthographic projection of the channel 21 on the substrate 10 is greater than or equal to 0.5 μm.

In the case where the minimum spacing D2 between the outer edge of the orthographic projection of the first gate 30 on the substrate 10 and the outer edge of the orthographic projection of the channel 21 on the substrate 10 is equal to or close to 0.5 μm, the first gate 30 may extend outside, so that the step region formed at the edge of the first gate 30 avoids the channel 21 of the active layer 20 to prevent the channel 21 of the active layer 20 from being formed on an uneven surface to ensure the conductivity of the channel 21 of the active layer 20.

In some other embodiments, the minimum spacing D2 between the outer edge of the orthographic projection of the first gate 30 on the substrate 10 and the outer edge of the orthographic projection of the channel 21 on the substrate 10 is greater than or equal to 5 μm.

In the case where the minimum spacing D2 between the outer edge of the orthographic projection of the first gate 30 on the substrate 10 and the outer edge of the orthographic projection of the channel 21 on the substrate 10 is equal to or close to 5 μm, the first gate 30 may extend to a great extent, so that the step region formed at the edge of the first gate 30 may avoid the channel 21 of the active layer 20 well to prevent the channel 21 of the active layer 20 from being formed on an uneven surface, so as to ensure the conductivity of the channel 21 of the active layer 20.

For example, the minimum spacing D2 between the outer edge of the orthographic projection of the first gate 30 on the substrate 10 and the outer edge of the orthographic projection of the channel 21 on the substrate 10 is any one of approximately 0.5 μm, 1 μm or 2 μm, and the embodiments of the present disclosure are not limited thereto.

In some embodiments, referring to FIGS. 7 and 8, the orthographic projection of the active layer 20 on the substrate 10 is located within the orthographic projection of the first gate 30 on the substrate 10.

Based on this, for the thin film transistor T, the orthographic projection of the channel 21 on the substrate 10 is set to be located within the orthographic projection of the first gate 30 on the substrate 10. Thus, the step region formed at the edge of the first gate 30 may avoid the active layer 20 to prevent the active layer 20 from being formed on an uneven surface to ensure the performance of the active layer 20.

In some embodiments, referring to FIGS. 7 and 8, the minimum spacing D4 between the outer edge of the orthographic projection of the first gate 30 on the substrate 10 and the outer edge of the orthographic projection of the active layer 20 on the substrate 10 is greater than or equal to 0.5 μm.

In the case where the minimum spacing D4 between the outer edge of the orthographic projection of the first gate 30 on the substrate 10 and the outer edge of the orthographic projection of the active layer 20 on the substrate 10 is equal to or close to 0.5 μm, the first gate 30 may extend outward, so that the step region formed at the edge of the first gate 30 avoids the active layer 20 to prevent the active layer 20 from being formed on an uneven surface, so as to ensure the performance of the active layer 20.

In some other embodiments, the minimum spacing D4 between the outer edge of the orthographic projection of the first gate 30 on the substrate 10 and the outer edge of the orthographic projection of the active layer 20 on the substrate 10 is greater than or equal to 5 μm. orthographic projection of the first gate 30 on the substrate 10 and the outer edge of the orthographic projection of the active layer 20 on the substrate 10 is equal to or close to 5 μm, the first gate 30 may extend outside to a great extent, so that the step region formed at the edge of the first gate 30 may avoid the active layer 20 well to prevent the active layer 20 from being formed on an uneven surface, so as to ensure the performance of the active layer 20.

For example, the minimum spacing D4 between the outer edge of the orthographic projection of the first gate 30 on the substrate 10 and the outer edge of the orthographic projection of the active layer 20 on the substrate 10 is any one of approximately 0.5 μm, 1 μm or 2 μm, and the embodiments of the present disclosure are not limited thereto.

It will be noted that, the description will be made by taking an example in which the minimum spacing D4 between the outer edge of the orthographic projection of the first gate 30 on the substrate 10 and the outer edge of the orthographic projection of the active layer 20 on the substrate 10 is approximately 0.5 μm, due to certain uncontrollable errors (e.g., manufacturing process errors, equipment accuracy, and measurement errors), in a case where the error floating range of the minimum spacing D4 floats within the range of 10%×0.5 μm, it may also be considered that the minimum spacing D4 is equal to 0.5 μm.

In addition, in some examples, due to certain uncontrollable errors (e.g., manufacturing process errors, equipment accuracy, and measurement errors), in a case where the error floating range of the minimum spacing D4 floats within the range of 5 %×0.5 μm, it may be considered that the minimum spacing D4 is equal to 0.5 μm.

In some embodiments, as shown in FIGS. 7 and 8, the minimum spacing D4 between the outer edge of the orthographic projection of the first gate 30 on the substrate 10 and the outer edge of the orthographic projection of the active layer 20 on the substrate 10 is less than or equal to 10 μm.

In the case where the minimum spacing D4 between the outer edge of the orthographic projection of the first gate 30 on the substrate 10 and the outer edge of the orthographic projection of the active layer 20 on the substrate 10 is equal to or close to 10 μm, the first gate 30 may extend outside to a great extent without greatly increasing the size of the thin film transistor T. In this case, the step region formed at the edge of the first gate 30 may avoid the active layer 20 well to prevent the active layer 20 from being formed on an uneven surface, so as to ensure the performance of the active layer 20.

In some embodiments, as shown in FIGS. 7 and 8, the minimum spacing D4 between the outer edge of the orthographic projection of the first gate 30 on the substrate 10 and the outer edge of the orthographic projection of the active layer 20 on the substrate 10 is in a range of 0.5 μm to 10 μm, inclusive.

Based on this, the step region formed at the edge of the first gate 30 may avoid the active layer 20 well to prevent the active layer 20 from being formed on an uneven surface to ensure the performance of the active layer 20; moreover, it may also prevent affecting the size of the thin film transistor T due to the excessive outward extension of the first gate 30.

In some other embodiments, the minimum spacing D4 between the outer edge of the orthographic projection of the first gate 30 on the substrate 10 and the outer edge of the orthographic projection of the active layer 20 on the substrate 10 is in a range of 0.5 μm to 3 μm, inclusive. In some other embodiments, the minimum spacing D4 between the outer edge of the orthographic projection of the first gate 30 on the substrate 10 and the outer edge of the orthographic projection of the active layer 20 on the substrate 10 is in a range of 0.5 μm to 5 μm, inclusive. Embodiments of the present disclosure are not limited to the above.

In some embodiments, referring to FIGS. 5 to 8, when the channel 21 of the active layer 20 is formed, the second gate 40 may be used as a mask to form the first heavily doped region 22 and the second heavily doped region 23 of the active layer 20. Thus, in a sectional view of the thin film transistor T taken along the first direction X (as shown in FIGS. 6 and 8), an orthographic projection of the second gate 40 on the substrate 10 substantially coincides with the orthographic projection of the channel 21 on the substrate 10.

Based on this, it is helpful to prevent the orthographic projection of the second gate 40 on the substrate 10 from overlapping with the orthographic projection of the first heavily doped region 22 and/or the second heavily doped region 23 on the substrate 10, thereby preventing from producing the problems of parasitic capacitance and parasitic resistance due to the overlapping region, which may help ameliorate the problems of the parasitic effect and signal delay in the thin film transistor T to improve the performance of the thin film transistor T.

It will be noted that, “substantially coincide” includes absolute coincidence and approximate coincidence. That is, a floating range of a gap between the orthographic projection of the second gate 40 on the substrate 10 and the orthographic projection of the channel 21 on the substrate 10 does not exceed the error threshold, and it may also be considered that the edge of the orthographic projection of the second gate 40 on the substrate 10 “coincides” relatively with the orthographic projection of the channel 21 on the substrate 10. The specific value of the error threshold is not limited in the present disclosure.

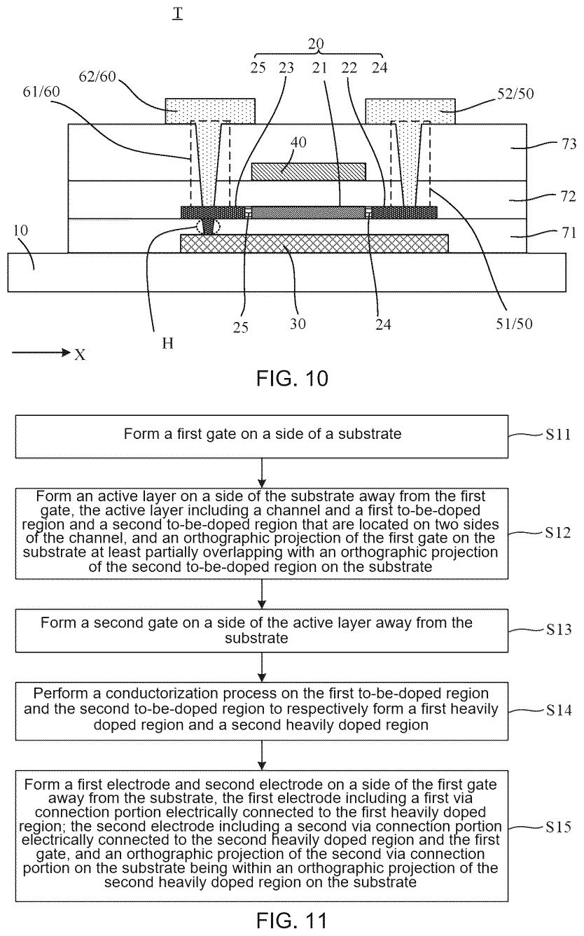

FIG. 9 is a diagram showing film layers of a thin film transistor, in accordance with some other embodiments, and FIG. 10 is a diagram showing film layers of a thin film transistor, in accordance with yet some other embodiments. FIG. 9 shows a thin film transistor in which the second via connection portion 61 and the first gate 30 are electrically connected in the first manner (direct electrical connection), and FIG. 10 shows a thin film transistor in which the second via connection portion 61 and the first gate 30 are electrically connected in the second manner (indirect electrical connection).

In some embodiments, referring to FIGS. 9 and 10, the active layer 20 further includes a first lightly doped drain (LDD) 24 and a second lightly doped drain (LDD) 25. The first lightly doped drain 24 is located between the first heavily doped region 22 and the channel 21, and the doping concentration of the first lightly doped drain 24 is less than the doping concentration of the first heavily doped region 22. The second lightly doped drain 25 is located between the second heavily doped region 23 and the channel 21, and the doping concentration of the second lightly doped drain 25 is less than the doping concentration of the second heavily doped region 23.

The first lightly doped drain 24 is disposed between the first heavily doped region 22 and the channel 21, and a second lightly doped drain 25 is disposed between the second heavily doped region 23 and the channel 21. That is, a lightly doped region having a doping concentration one order of magnitude less than that of the heavily doped region is provided between the channel 21 and the heavily doped region. The lightly doped region (the first lightly doped drain 24 and the second lightly doped drain 25) is equivalent to a large resistor connected in series between the channel 21 and the source and drain (the first electrode 50 and the second electrode 60) of the thin film transistor T, which is beneficial to reducing the horizontal electric field of the channel 21 and reducing the hot carriers generated by the impact ionization caused by the electric field acceleration, thereby effectively suppressing the leakage current of two orders of magnitude.

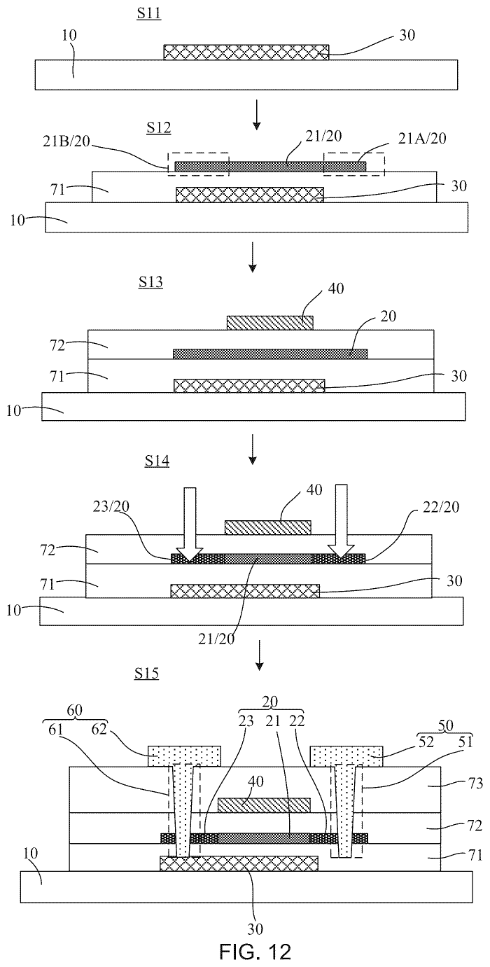

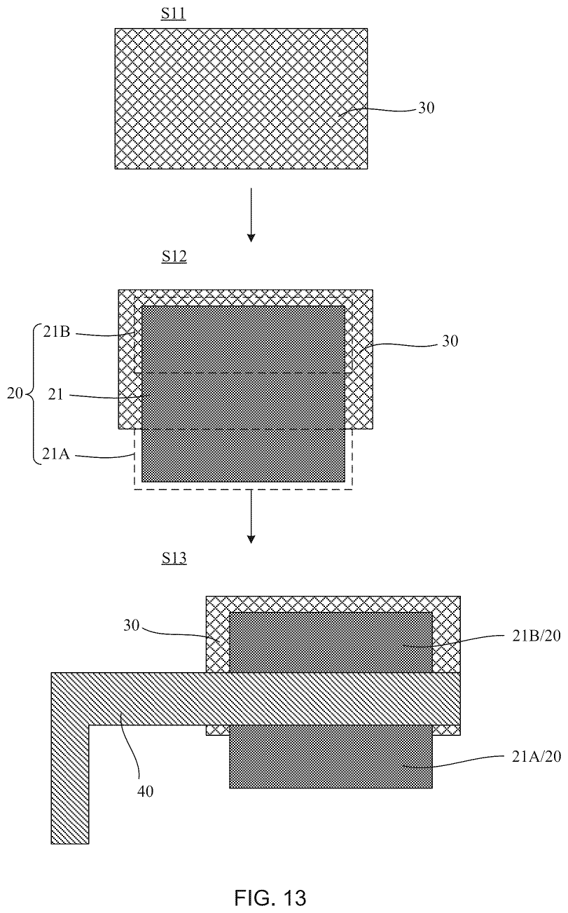

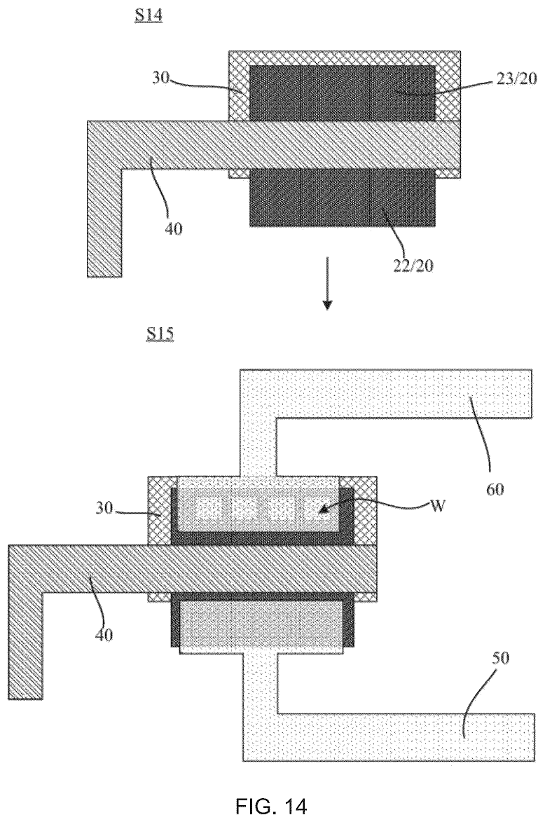

FIG. 11 is a flowchart of a manufacturing method for a thin film transistor, in accordance with some embodiments; FIG. 12 is a structural diagram showing film layers corresponding to steps in FIG. 11; FIG. 13 is a top view corresponding to some steps in FIG. 11; and FIG. 14 a top view corresponding to some other steps in FIG. 11. The substrate is not shown in FIGS. 13 and 14.

In some embodiments, referring to FIGS. 11 to 14, some embodiments of the present disclosure provide a manufacturing method for a thin film transistor, and the manufacturing method includes the following.

In S11, a first gate 30 is formed on a side of the substrate 10.

In S12, an active layer 20 is formed on a side of the substrate 10 away from the first gate 30; the active layer 20 includes a channel 21, and a first to-be-doped region 21A and a second to-be-doped region 21B located on two sides of the channel 21, and an orthographic projection of the first gate 30 on the substrate 10 at least partially overlaps with an orthographic projection of the second to-be-doped region 21B on the substrate 10.

In S13, a second gate 40 is formed on a side of the active layer 20 away from the substrate 10.

In S14, a conductorization process is performed on the first to-be-doped region 21A and the second to-be-doped region 21B to respectively form a first heavily doped region 22 and a second heavily doped region 23. By using a mask process, a conductorization process is performed on the first to-be-doped region 21A to form a first heavily doped region 22 of the active layer 20, and a conductorization process is performed on the second to-be-doped region 21B to form a second heavily doped region 23 of the active layer 20.

In S15, a first electrode 50 and a second electrode 60 are formed on a side of the first gate 30 away from the substrate 10; the first electrode 50 includes a first via connection portion 51, and the first via connection portion 51 is electrically connected to the first heavily doped region 22; the second electrode 60 includes a second via connection portion 61, and the second via connection portion 61 is electrically connected to both the second heavily doped region 23 and the first gate 30, and an orthographic projection of the second via connection portion 61 on the substrate 10 is located within an orthographic projection of the second heavily doped region 23 on the substrate 10.

In step S15, the formed first electrode 50 includes the first via connection portion 51 and a first main portion 52, and the formed second electrode 60 includes the second via connection portion 61 and a second main portion 62. The first main portion 52 of the first electrode 50 and the second main portion 62 of the second electrode 60 are formed on a side of the first gate 30 away from the substrate 10. The first via connection portion 51 of the first electrode 50 and the second via connection portion 61 of the second electrode 60 are formed between the main portion (the first main portion 52 and the second main portion 52) and the first gate 30, so that the first main portion 52 is electrically connected to the first heavily doped region 22 through the first via connection portion 51, and the second main portion 62 is electrically connected to both the second heavily doped region 23 and the first gate 30 through the second via connection portion 61.

To sum up, in the manufacturing method for a thin film transistor provided in the embodiments of the present disclosure, the orthographic projection of the first gate 30 on the substrate 10 is set to at least partially overlap with the orthographic projection of the second heavily doped region 23 on the substrate 10, and the orthographic projection of the second via connection portion 61 on the substrate 10 is located within the orthographic projection of the second heavily doped region 23 on the substrate 10. Thus, it is possible to not only achieve that the second via connection portion 61 may electrically connect the main portion 62 of the second electrode 60 to the second heavily doped region 23 and the first gate 30, but also ameliorate the problem of increasing the size of the thin film transistor T due to the provision of the second via connection portion 61 of the second electrode 60. That is, for the thin film transistor T provided in the embodiments of the present disclosure, it may be possible to ameliorate the floating body effect of the thin film transistor T without changing the size of the thin film transistor T as much as possible, so as to improve the display quality of the display apparatus 300 while ensuring the pixels per inch of the display apparatus 300.

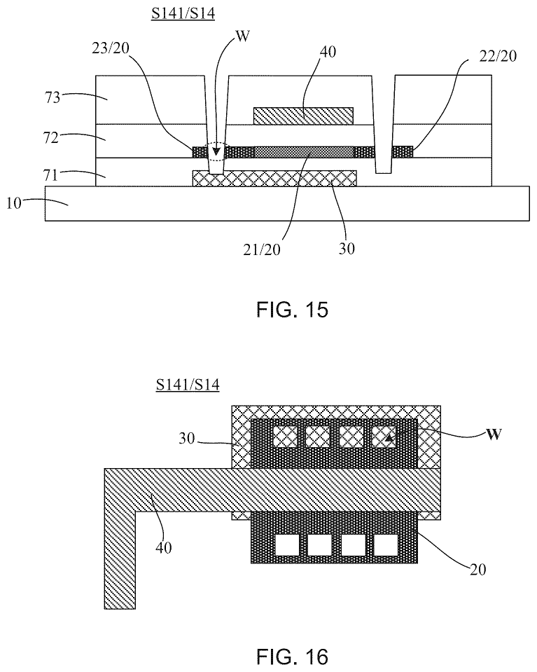

FIG. 15 is a structural diagram showing film layers corresponding to the step S14 in FIG. 11; FIG. 16 is a top view corresponding to the step S14 in FIG. 11.

In some embodiments, referring to FIGS. 15 and 16, in the manufacturing method for a thin film transistor, the step S14 is before the step S15, that is, before forming the first electrode 50 and the second electrode 60 on the side of the first gate 30 away from the substrate 10, the method may further include S141: forming a via hole W in the second heavily doped region 23.

Based on this, in the step S15, forming the second electrode 60 includes: the second via connection portion 61 of the second electrode 60 penetrating the via hole W to be electrically connected to the first gate 30. That is, when forming the second electrode 60, the via hole W of the second heavily doped region 23 are filled with the other end of the second via connection portion 61, and the other end of the second via connection portion 61 penetrates the via hole W of the second heavily doped region 23 and extends to be electrically connected to the first gate 30 at the lower position thereof, so that the second via connection portion 61 is used to be electrically connected to both the second heavily doped region 23 and the first gate 30. Thus, there is no need to additionally provide a connection portion that needs to avoid the active layer 20 of the thin film transistor T, which may ameliorate the problem of the size of the thin film transistor T being increased due to the connection portion. Furthermore, since the thin film transistor T is electrically connected to the second heavily doped region 23 and the first gate 30 by extending the second via connection portion 61, there is no need to increase the process of the thin film transistor T.

In addition, by forming via hole in the second heavily doped region 23 of the thin film transistor T, the second via connection portion 61 is electrically connected to the first gate 30 via the second heavily doped region 23, so that the longitudinal space between the second heavily doped region 23 and the first gate 30 is fully used, that is, the internal space of the thin film transistor T is fully used, so that the size of the thin film transistor T will not be increased. In a case where the thin film transistor T is subsequently applied to the light-emitting driving circuit Q, it will not be limited by the area and size, and will not affect the pixel density of the display apparatus 300.

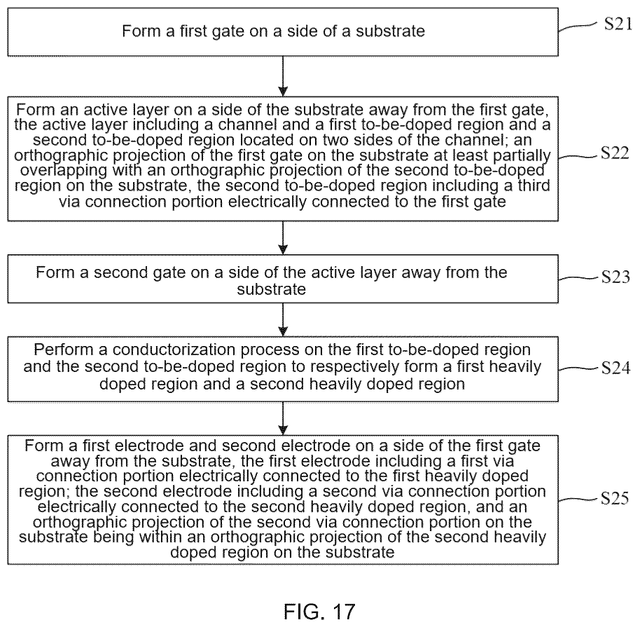

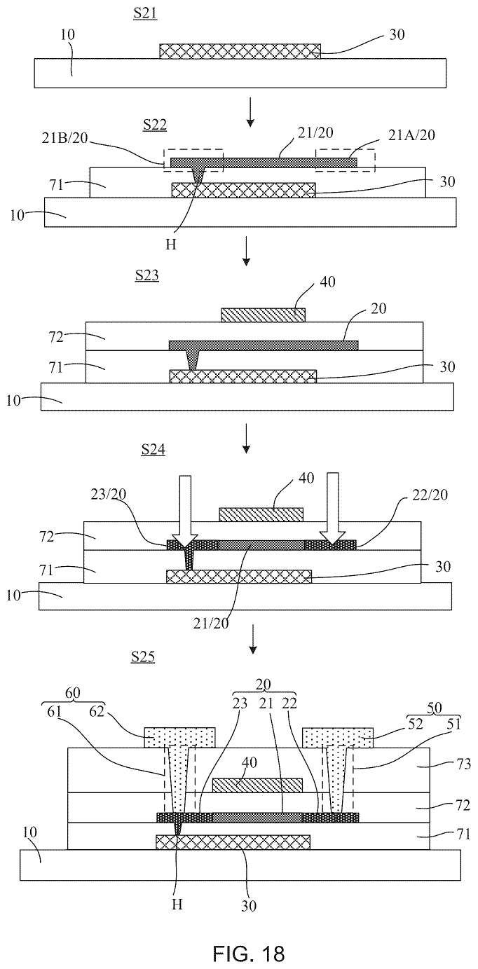

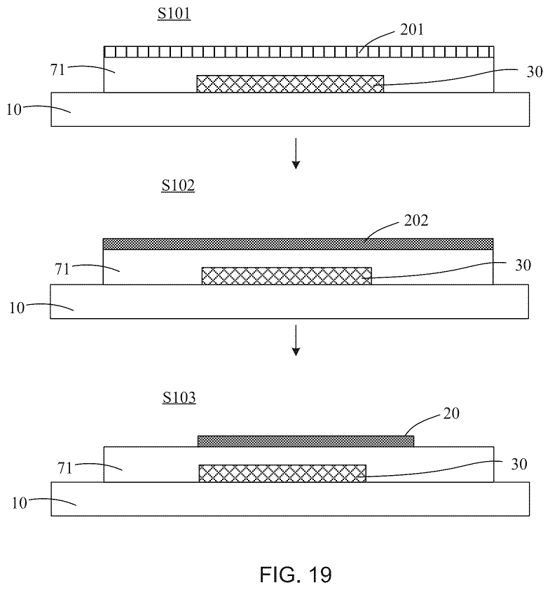

FIG. 17 is a flowchart of a manufacturing method for a thin film transistor, in accordance with some embodiments; FIG. 18 is a structural diagram showing film layers corresponding to steps in FIG. 17.

In some embodiments, referring to FIGS. 17 and 18, the manufacturing method for a thin film transistor includes the following.

In S21, a first gate 30 is formed on a side of the substrate 10.

In S22, an active layer 20 is formed on a side of the substrate 10 away from the first gate 30; the active layer 20 includes a channel 21, and a first to-be-doped region 21A and a second to-be-doped region 21B that are located on two sides of the channel 21; the orthographic projection of the first gate 30 on the substrate 10 at least partially overlaps with the orthographic projection of the second to-be-doped region 21B on the substrate 10, and the second to-be-doped region 21B includes a third via connection portion H, and the third via connection portion H is electrically connected to the first gate 30.

Before the step S22 and after step S21, the method may include: forming a first gate insulating layer 71 on a side of the first gate 30 away from the substrate 10, and forming via hole(s) in the first gate insulating layer 71 to expose the first gate 30.

In step S22, an active layer 20 is formed on a side of the substrate 10 away from the first gate 30, that is, an active layer 20 is formed on a side of the first gate insulating layer 71 away from the first gate 30. When the active layer 20 is formed, the via hole(s) in the first gate insulating layer 71 are filled with the third via connection portion H of the second to-be-doped region 21B, so that the third via connection portion H penetrates the via hole(s) and is electrically connected to the first gate 30.

It will be noted that, in this step, via hole(s) are only formed in the first gate insulating layer 71 at a position corresponding to the subsequent second to-be-doped region 21B. That is, there is no need to form the via hole(s) in the first gate insulating layer 71 at the position corresponding to the first to-be-doped region 21A.

Based on this, in the subsequent manufacturing method for the thin film transistor, when the first electrode 50 is formed, the first electrode 50 will not extend to the first gate insulating layer 71; that is, the problem of a short circuit between the first electrode 50 and the first gate 30 will not occur caused by a case that the first electrode 50 will not extend to the position of the first gate 30. Therefore, when manufacturing the first gate 30 of the thin film transistor, there is no need to consider the problem of avoiding the first electrode 50, the first gate 30 may extend as much as possible, so that the orthographic projection of the subsequently formed channel 21 of the active layer 20 on the substrate 10 is located within the orthographic projection of the first gate 30 on the substrate 10. With such configuration, an orthographic projection of the active layer 20 on the substrate 10 may be located within the orthographic projection of the first gate pattern 30 on the substrate 10.

With such configuration, the step region formed at the edge of the first gate 30 may avoid the active layer 20 (the channel 21 of the active layer 20) to prevent the active layer 20 from being formed on an uneven surface, thereby ensuring the performance of the active layer 20. substrate 10.

In S24, a conductorization process is performed on the first to-be-doped region 21A and the second to-be-doped region 21B to respectively form a first heavily doped region 22 and a second heavily doped region 23.

In S25, a first electrode 50 and a second electrode 60 are formed on a side of the first gate 30 away from the substrate 10; the first electrode 50 includes a first via connection portion 51, and the first via connection portion 51 is electrically connected to the first heavily doped region 22; the second electrode 60 includes a second via connection portion 61, and the second via connection portion 61 is electrically connected to both the second heavily doped region 23; an orthographic projection of the second via connection portion 61 on the substrate 10 is located within an orthographic projection of the second heavily doped region 23 on the substrate 10.

In summary, in the manufacturing method for a thin film transistor provided by the embodiments of the present disclosure, the second heavily doped region 23 may include a third via connection portion H, and the third via connection portion H penetrates the first gate insulating layer 71, so that the second heavily doped region 23 is electrically connected to the first gate 30. Furthermore, the second electrode 60 may be electrically connected to the first gate 30 through the second via connection portion 61 and the second heavily doped region 23 in sequence. That is, the second electrode 60 may be indirectly electrically connected to the first gate 30 through the second via connection portion 61.

Based on this, there is no need to additionally provide a connection portion that needs to avoid the active layer 20 of the thin film transistor T, which may ameliorate the problem of the size of the thin film transistor T being increased due to the connection portion. Furthermore, the longitudinal space between the second heavily doped region 23 and the first gate 30 may be fully utilized, i.e., the internal space of the thin film transistor T may be fully utilized, so that the size of the thin film transistor T will not be increased. In a case where the thin film transistor T is subsequently applied to the light-emitting driving circuit Q, it will not be limited by the area and size, so that the pixels per inch of the display apparatus 300 will not be affected.

FIG. 19 is a structural diagram of a manufacturing method for a thin film transistor, in accordance with some embodiments.

In some embodiments, referring to FIG. 19, and FIG. 12 or 18, in the step S12 (as shown in FIG. 12) or step S22 (as shown in FIG. 18), “forming an active layer 20 on a side of the substrate 10 away from the first gate 30” may include:

S101: forming an amorphous silicon layer 201 on a side of the substrate 10 away from the first gate 30;

S102: performing an excimer laser annealing (ELA) process on the amorphous silicon layer 201 to form an initial active layer 202 of polycrystalline silicon; and

S103: etching the initial active layer 202 of polycrystalline silicon to form the active layer 20.

In the embodiments of the present disclosure, the orthographic projection of the channel 21 of the thin film transistor T on the substrate 10 may be set to be within the orthographic projection of the first gate 30 on the substrate 10. Thus, the step region formed at the edge of the first gate 30 may be made to avoid the channel 21 of the active layer 20 to prevent the channel 21 of the active layer 20 from being formed on an uneven surface to ensure the conductivity of the channel 21 of the active layer 20.

In some embodiments, referring to FIG. 12 or 18, in the step S14 (as shown in FIG. 12) or step S24 (as shown in FIG. 18), “by using a mask process, a conductorization process is performed on the first to-be-doped region 21A and the second to-be-doped region 21B to form a corresponding first heavily doped region 22 and second heavily doped region 23” may include the following.

A conductorization process, by taking the first gate 30 as a mask, is performed on the first to-be-doped region 21A and the second to-be-doped region 21B by using a self-alignment process to form the corresponding first heavily doped region 22 and the second heavily doped region 23. An orthographic projection of the second gate 40 on the substrate 10 partially overlaps with the orthographic projection of the channel portion 21 on the substrate 10.

As described above, not only is there no need to provide a separate mask, but it may also help prevent the orthographic projection of the second gate 40 on the substrate 10 from overlapping with the orthographic projection of the first heavily doped region 22 and/or the second heavily doped region 23 on the substrate 10, thereby preventing the problem of parasitic capacitance and parasitic resistance being produced in the overlapping region. Thus, it may be possible to help ameliorate the problems of parasitic effect and signal delay in the thin film transistor T, so as to improve the performance of The foregoing descriptions are merely specific implementations of the present disclosure, but the protection scope of the present disclosure is not limited thereto, any variations or substitutions that those skilled in the art could conceive of within the technical scope of the present disclosure shall fall within the protection scope of the present disclosure. Therefore, the protection scope of the present disclosure should be determined by the protection scope of the claims.

What is claimed is:

1. A thin film transistor, comprising:
a substrate;
an active layer located on a side of the substrate, the active layer including a channel and a first heavily doped region and a second heavily doped region that are located on two sides of the channel;
a first gate located on a side of the active layer proximate to the substrate;
a second gate located on a side of the active layer away from the first gate, an orthographic projection of the first gate on the substrate at least partially overlapping with an orthographic projection of the second heavily doped region on the substrate; and
a first electrode and a second electrode, the first electrode including a first main portion and a first via connection portion, the second electrode including a second main portion and a second via connection portion, and the first main portion and the second main portion being located on a side of the second gate away from the active layer;
wherein the first via connection portion is electrically connected to the first main portion and the first heavily doped region, the second via connection portion is electrically connected the second main portion and the second heavily doped region and first gate, and an orthographic projection of the second via connection portion on the substrate is located within the orthographic projection of the second heavily doped region on the substrate.

2. The thin film transistor according to claim 1, wherein the second heavily doped region includes at least one via hole, an end of the second via connection portion is electrically connected to the second main portion, and another end of the second via connection portion penetrates the via hole to be electrically connected to the first gate.

3. The thin film transistor according to claim 2, wherein the orthographic projection of the first gate on the substrate is non-overlapping with an orthographic projection of the first via connection portion on the substrate.

4. The thin film transistor according to claim 1, wherein a minimum spacing between the orthographic projection of the first gate on the substrate and an orthographic projection of the first via connection portion on the substrate is greater than or equal to 0.5 μm.

5. The thin film transistor according to claim 1, wherein an orthographic projection of the channel on the substrate is located within the orthographic projection of the first gate on the substrate, and a minimum spacing between an outer edge of the orthographic projection of the first gate on the substrate and an outer edge of the orthographic projection of the channel on the substrate is greater than or equal to 0.5 μm.

6. The thin film transistor according to claim 5, wherein the orthographic projection of the second heavily doped region on the substrate is located within the orthographic projection of the first gate on the substrate.

7. The thin film transistor according to claim 6, wherein in a first direction, the first gate includes a first side and a second side that are oppositely arranged, and the first side is located on a side of the second side away from the first via connection portion; the first direction is a direction from the first electrode to the second electrode; and
a minimum spacing between an orthographic projection of the first side of the first gate on the substrate and an orthographic projection of a third side, away from the first heavily doped region, of the second heavily doped region on the substrate is greater than or equal to 0.5 μm.

8. The thin film transistor according to claim 7, wherein the minimum spacing between the orthographic projection of the first second side of the first gate on the substrate and the orthographic projection of the third side, away from the first heavily doped region, of the second heavily doped region on the substrate is less than or equal to 10 μm.

9. The thin film transistor according to claim 1, wherein an end of the second via connection portion is electrically connected to the second main portion of the second electrode, and another end of the second via connection portion is electrically connected to the first gate through the second heavily doped region.

10. The thin film transistor according to claim 9, wherein an orthographic projection of the channel on the substrate is located within the orthographic projection of the first gate on the substrate, and a minimum spacing between an outer edge of the orthographic projection of the first gate on the substrate and an outer edge of the orthographic projection of the channel on the substrate is greater than or equal to 0.5 μm.

11. The thin film transistor according to claim 9, wherein an orthographic projection of the active layer on the substrate is located within the orthographic projection of the first gate on the substrate.

12. The thin film transistor according to claim 9, wherein a minimum spacing between an outer edge of the orthographic projection of the first gate on the substrate and an outer edge of an orthographic projection of the active layer on the substrate is greater than or equal to 0.5 μm.

13. The thin film transistor according to claim 12, wherein the minimum spacing between the outer edge of the orthographic projection of the first gate on the substrate and the outer edge of the orthographic projection of the active layer on the substrate is less than or equal to 10 μm.

14. The thin film transistor according to claim 1, wherein the active layer further includes a first lightly doped drain and a second lightly doped drain; wherein
the first lightly doped drain is located between the first heavily doped region and the channel, and a doping concentration of the first lightly doped drain is less than a doping concentration of the first heavily doped region; and
the second lightly doped drain is located between the second heavily doped region and the channel, and a doping concentration of the second lightly doped drain is less than a doping concentration of the second heavily doped region.

15. The thin film transistor according to claim 1, wherein in a sectional view of the thin film transistor taken along a first direction, an orthographic projection of the second gate on the substrate substantially coincides with an orthographic projection of the channel on the substrate; the first direction is a direction from the first electrode to the second electrode.

16. The thin film transistor according to claim 1, wherein a thickness of the active layer is in a range of 100 Å to 1000 Å, inclusive.

17. A manufacturing method for a thin film transistor, comprising:
forming a first gate on a side of a substrate;
forming an active layer on a side of the substrate away from the first gate, wherein the active layer includes a channel and a first to-be-doped region and a second to-be-doped region that are located on two sides of the channel, and an orthographic projection of the first gate on the substrate at least partially overlaps with an orthographic projection of the second to-be-doped region on the substrate;
forming a second gate on a side of the active layer away from the substrate;
performing a conductorization process on the first to-be-doped region and the second to-be-doped region to respectively form a first heavily doped region and a second heavily doped region; and
forming a first electrode and a second electrode on a side of the first gate away from the substrate, wherein the first electrode includes a first via connection portion, the first via connection portion is electrically connected to the first heavily doped region; the second electrode includes a second via connection portion, the second via connection portion is electrically connected to the second heavily doped region and the first gate, and an orthographic projection of the second via connection portion on the substrate is located within an orthographic projection of the second heavily doped region on the substrate.

18. The manufacturing method according to claim 17, wherein before forming the first electrode and the second electrode on the side of the first gate away from the substrate, the manufacturing method further comprises:
forming a via hole in the second heavily doped region; wherein forming the second electrode includes: the second via connection portion of the second electrode penetrating the via hole to be electrically connected to the first gate.

19. A manufacturing method for a thin film transistor, comprising:
forming a first gate on a side of a substrate;
forming an active layer on a side of the substrate away from the first gate, wherein the active layer includes a channel and a first to-be-doped region and a second to-be-doped region that are located on two sides of the channel, an orthographic projection of the first gate on the substrate at least partially overlaps with an orthographic projection of the second to-be-doped region on the substrate, the second to-be-doped region includes a third via connection portion, and the third via connection portion is electrically connected to the first gate;
forming a second gate on a side of the active layer away from the substrate;
performing a conductorization process on the first to-be-doped region and the second to-be-doped region to respectively form a first heavily doped region and a second heavily doped region; and
forming a first electrode and a second electrode on a side of the first gate away from the substrate, wherein the first electrode includes a first via connection portion, and the first via connection portion is electrically connected to the first heavily doped region; the second electrode includes a second via connection portion, and the second via connection portion is electrically connected to the second heavily doped region; an orthographic projection of the second via connection portion on the substrate is within an orthographic projection of the second heavily doped region on the substrate.

20. A light-emitting substrate, comprising the thin film transistor according to claim 1.
